(19) United States
(12) Patent Application Publication
(10) Pub. No.: US 2026/0242205 A1
(43) Pub. Date: Aug. 20, 2026

(54) MICROELECTRONIC DEVICES FABRICATED WITH 3D LITHOGRAPHY

(71) Applicant: Atum Works Inc., Mountain View, CA (US)

(72) Inventors: Malcolm George Adams Tisdale, Palo Alto, CA (US); Lucas Layne Brass Pabarcius, Woodside, CA (US)

(21) Appl. No.: 19/532,383

(22) Filed: Feb. 6, 2026

Related U.S. Application Data
(60) Provisional application No. 63/757,712, filed on Feb. 12, 2025.

(51) Int. Cl. B81B 3/00; B81C 1/00

(52) U.S. Cl. CPC B81B 3/0027; B81C 1/00206; B81B 2201/0214; B81B 2201/0264; B81B 2203/0163; B81B 2203/04

(57) ABSTRACT

A compliant contact includes a body including and extending between a first end and a second end. The second end is configured to couple to an electrically interfacing device. A conductive material defines an outer surface of the body, and the body is formed with a 3D lithographic process and a metallization process.

### RELATED APPLICATIONS

This application claims priority to U.S. Patent Application 63/757,712, filed Feb. 12, 2025, the entire disclosure of which is incorporated herein by reference for all purposes.

### BACKGROUND

### Field

The field relates to microelectronic structures formed with lithography.

### Description of the Related Art

Probe cards, test sockets, and other devices (e.g., final product sockets for exchangeable incorporation of devices into larger systems) can include probes or contacts fabricated by micro-electromechanical system (MEMS) processes, which can include 2D patterning by bulk/surface micromachining, lithographic techniques, etc. Typical designs use cantilever and sinusoidal shapes to provide contact compliancy for mechanical and electrical contact. The compliant contacts (e.g., probes) can be robotically or manually transferred to contacts on a board (e.g., probe card) and integrated by way of solder or complex mechanical interfaces. In addition to the expense of manufacture and assembly, such conventional designs face limitations relating to compliance and force issues, density, and misalignment compensation. Mechanical compliance to ensure consistent contact and minimal pad damage across an array must be balanced against electrical requirements. On the one hand, increasing compliance is often accomplished by lengthening cantilever beams or reducing metal thickness, which can compromise lateral stability or current capacity. On the other hand, providing cantilevered contacts with sufficiently thick conductors can yield reduced current carrying capacity and, in some cases, can result in an excessive deflection force in operation, particularly when multiplied across the number of compliant contacts simultaneously used, such as in a wafer-level or die-level test or burn-in process. This tends to limit the number of compliant contacts and therefore contacts of the device-under-test that can be simultaneously tested.

Thus, improvements are desired to form compliant contacts (e.g., probes) for microelectronic devices that can be provided with sufficient density and mechanical compliance without sacrificing electrical considerations.

### BRIEF DESCRIPTION OF THE DRAWINGS

Features, aspects, and advantages of the disclosure are described with reference to drawings of certain embodiments, which are intended to illustrate, but not to limit, the present disclosure. It is to be understood that the accompanying drawings, which are incorporated in and constitute a part of this specification, are for the purpose of illustrating concepts disclosed herein and may not be to scale.

FIGS. 1A-1E are schematics illustrating a microelectronic device formed with 3D lithography, according to one embodiment. FIG. 1A is an isometric view of the microelectronic device, which includes a plurality of compliant contacts electrically connected to contact pads in or on a substrate. FIG. 1B is a cross-sectional view of a portion of the compliant contacts in FIG. 1A. FIG. 1C is a magnified view of a foot-like structure that can be provided at the base of a compliant contact for offgassing purposes. FIG. 1D is a plan view of a guide plate. FIG. 1E is a cross-sectional view of a portion of the compliant contacts in FIG. 1A with a guide plate.

FIGS. 2A-2B illustrate different possible configurations of a compliant contact, according to some embodiments. FIG. 2A shows a compliant contact having a core surrounded by a coil structure or spring. FIG. 2B shows a compliant contact having a support surrounded by two compliant, elongate elements.

FIGS. 3A-3D illustrate possible configurations of compliant contacts, according to some embodiments. FIG. 3A is a schematic illustrating the nesting of two compliant contacts. FIG. 3B is a schematic illustrating the nesting of two compliant contacts, where the compliant contact design was generated by artificial intelligence and then fabricated using 3D lithographic processes. FIG. 3C illustrates a cross-section of an array of compliant contacts and a 3D sweep path. FIG. 3D illustrates nine compliant contacts, where each compliant contact has a spring or spring-like configuration.

FIGS. 4A-4I illustrate a compliant contact and various compliant contact tips, according to some embodiments. FIG. 4A is a schematic of a portion of a compliant contact having scaffolding that is surrounded by a conductive material and a tip. FIG. 4B shows a tip having a shape corresponding to a sphere. FIG. 4C shows a tip having a shape corresponding to a hyperboloid. FIG. 4D shows a tip having a shape corresponding to a pyramid. FIG. 4E shows a tip having a shape corresponding to a wedge. FIG. 4F is a top view of FIG. 4E. FIG. 4G shows a tip having a shape corresponding to a crown or a multi-wedge. FIG. 4H shows a tip having a shape corresponding to a screw tip. FIG. 4I shows a tip having multiple contact protrusions.

FIG. 5 is a partially cut-away schematic isometric view of a compliant contact having a plunger that plunges into liquid metal, and spiraling coils that surround the plunger, according to one embodiment.

FIG. 6 is a schematic view of a compliant contact at least partially embedded in a porous material, according to one embodiment.

FIGS. 7A-7B schematically illustrate compliant contacts having multiple compliant elements in the form of elongated radial and azimuthal flexures, according to some embodiments.

FIG. 8 schematically illustrates a compliant contact having a ribbon morphology for compliance, according to one embodiment.

FIG. 9 schematically illustrates a compliant contact with a ribbon morphology surrounding an internal structure for tailoring compliance and stiffness, according to one embodiment.

FIG. 10 schematically illustrates a compliant contact having a core with a tip, and an external support structure for tailoring compliance and stiffness, according to one embodiment.

FIG. 11 schematically illustrates a compliant contact having a core with a tip, one or more coils surrounding a portion of the core, and an external support structure for tailoring compliance and stiffness, according to one embodiment.

FIG. 12 schematically illustrates a compliant contact having a core with a tip, with multiple coils of different geometries surrounding a portion of the core, according to one embodiment.

FIG. 13 schematically illustrates a compliant contact having a first portion that spirals in one direction and a second portion that spirals in an opposite direction, according to one embodiment.

FIG. 14 schematically illustrates a compliant contact having a lattice structure, according to one embodiment.

FIG. 15 schematically illustrates a compliant contact having a lattice-like structure, according to one embodiment.

FIGS. 16A-16F are schematics showing the formation of compliant contacts each having a scaffold formed with a plurality of template elements and then coated in a conductive material, according to one embodiment. FIGS. 16A, 16C, and 16E show the fabrication process for three compliant contacts on a substrate. FIGS. 16B, 16D, and 16F show a magnified view of the fabrication process for one of the three compliant contacts.

FIG. 17A is a schematic isometric view of a compliant contact like those of FIGS. 16A-16F, while FIGS. 17B-17F are schematic cross sections showing different possible compositions of multiple polymer templates and coatings to form the compliant contact, according to some embodiments.

FIG. 18 is a schematic side cross-section of a plurality of sub-arrays of compliant contacts, according to one embodiment.

FIG. 19 is schematic view of a plurality of sub-array platforms, where each platform can have a plurality of compliant contacts on a first surface and a plurality of conductive supports on a second surface opposite the first surface, according to one embodiment.

FIG. 20 is a side cross-section of a compliant contact having a two-part core surrounded by a spring, according to one embodiment.

FIGS. 21A-21B are side cross-sections of a compliant contact having a two-part core surrounded by a spring, and a detent for keeping the parts of the core engaged, according to the one embodiment.

Like reference numbers are used to describe like features throughout the description and drawings.

### DETAILED DESCRIPTION

Although several embodiments, examples, and illustrations are disclosed below, it will be understood by those of ordinary skill in the art that the innovative aspects described herein extend beyond the specifically disclosed embodiments, examples, and illustrations and include other uses and obvious modifications and equivalents thereof. Embodiments are described with reference to the accompanying figures, wherein like numerals refer to like elements throughout. The terminology used in the description presented herein is not intended to be interpreted in any limited or restrictive manner simply because it is being used in conjunction with a detailed description of some specific embodiments. In addition, the embodiments can comprise several novel features and no single feature is solely responsible for its desirable attributes or is essential to practicing the innovative aspects herein described.

Microelectronics, including integrated circuits and packaging components for the same, have become increasingly complex and expensive. As such, reliable, durable, and high-density microelectronic testing devices (e.g., contact probe cards, probe cards, etc.) are needed to ensure the quality of integrated circuits and other microelectronic components. Recent contact probe cards (or wafer probe cards) are generally produced using planar, two-dimensional (2D) micro-electromechanical system (MEMS) processes, including bulk/surface micromachining or other photolithographic techniques. In such contact probe cards, the contact probes themselves are often assembled into position on the card by hand or are positioned with a robotic pick-and-place setup. The contact probes (or probes) can have a few geometries that may be optimized using various algorithms for specific deflection profiles. For example, the contact probes may include cantilevers or sinusoidal shapes (e.g., ribbon-like structures). The same considerations can apply to sockets with compliant contacts for other purposes, such as for receiving exchangeable microelectronic devices in a package or a larger system.

In view of the development of increasingly complex devices to be tested, such contact probe cards face limitations. Some of the limitations are a consequence of the 2D-patterned MEMS geometries. One limitation is regarding compliance and force. Compliant contacts are designed to have a threshold level of current carrying capacity, and so for some compliant contacts with sufficient current carrying capacity, contact pressures can be too high at designed deflections, which in turn leads to limits on the total number of compliant contacts that can interface with the microelectronics devices (e.g., the total number of contact probes per contact probe card) to keep the total down-force on a microelectronics device or an electrically interfacing device (e.g., device under test (DUT)) manageable. Another way to think of this is that compliant contacts (e.g., probes), such as those for implementation in devices like probe cards, test sockets, and sockets for exchangeable devices, typically have a certain pitch so that they can interface with a microelectronic device (e.g., chip). For that given pitch, different spaces or areas are used for different purposes. For example, some space is used for fixturing (e.g., implementing a guide plate), and some space is used or dedicated to tolerance stack up. Whatever space remains should be able to allow for sufficient contact force between the compliant contact and the device to be contacted, and sufficient cross-sectional area to carry current. The contact force facilitates scrubbing through or breaking through an oxide layer of the device or contact pad to which the compliant contact is to couple, so as to yield a meaningful, consistent result on each contact of the microelectronic device (e.g., DUT). Thus, a balancing act occurs in trying to ensure that there is sufficient contact force and there is enough remaining material to be able to carry enough current without melting.

Another related limitation is the density of compliant contacts, which is limited owing to limitations in the fabrication process and assembly of the larger device incorporating the compliant contacts, such as contact probe cards. Another limitation relates to misalignment compensation. For example, small out-of-plane offsets for a contact probe card or a socket can often lead to large mechanical overtravel (OT) or design tolerances, which may result in increasing contact forces and limiting the array pitch.

Some of the limitations are a consequence of mechanical and electrical constraints. When fabricating sockets or probe cards, mechanical compliance considerations are balanced with electrical requirement considerations. Regarding mechanical compliance, it is desirable to provide consistent contact and minimal damage to the microelectronics (e.g., DUT) pads being contacted. Concurrently, the compliant contacts are to be designed to have high current-carrying capacity, stable contact resistance, etc. For compliant contacts manufactured by 2D patterning techniques, increasing compliance often leads to the lengthening of the compliant contacts (which may be beams) or reducing their thickness, which can compromise lateral stability and/or current carrying capacity.

Three-dimensional (3D) microfabrication methods such as 3D lithography (e.g., two-photon lithography, multi-photon lithography, etc.) can produce complex 3D structures with sub-micron resolution on a wafer scale (or centimeter scale). With 3D lithographic processes, microelectronic devices, including the compliant contacts or probes, can be fabricated to address the limitations existing with conventional methods. For example, compliant contacts can be fabricated to have a variety of complex or intricate designs, such as different spring and/or flexure architectures. The configurations can include helices, spirals, lattices, multi-beam flexures, various metamaterials, 3D origami/kiragami, 3D computationally designed structures (including artificial intelligence (AI)-designed structures), etc. 3D lithographic processes also allow for tunable force-deflection curves, which enables ultra-low force at the compliant contact tip (e.g., probe tip), and controlled rotary scrubbing. Furthermore, the complexity afforded by 3D lithography can also enable the provision of multiple components for a compliant contact, such that compliancy can be provided by separate parts from the main conductors, allowing tuning of mechanical and electrical properties without the trade-offs faced by MEMS contacts. Lateral load handling can also be improved, as the 3D lithographic processes can readily implement 3D support geometries. In some cases, integrated microfluidic features for unique contact methods can be implemented (e.g., liquid-metal-filled chambers, multi-part sliding contacts, vacuum assistance, etc.). Additionally, the 3D lithographic processes can facilitate hierarchical, multi-level compliance within a microelectronic device incorporating the compliant contacts, such as probe cards, test sockets, and final product sockets. This is beneficial for addressing misalignment issues and compensation for non-planarity across various length scales.

3D lithographic processes can also enable mass manufacturing of such compliant contacts and microelectronic devices at faster rates as compared to conventional processes. For example, conventional processes may take weeks to months to produce a contact probe card or microelectronic testing device, whereas the 3D lithographic process may take days (e.g., a day) to produce a contact probe card or microelectronic testing device. In conventional processes, the individual probes are fabricated and then assembled with a pick-and-place process, which is time intensive. In contrast, 3D lithographic processes can enable fabrication of arrays of probes in their final or near-final assembled state, eliminating or at least reducing the implementation of pick-and-place processes and decreasing fabrication time. Moreover, 3D lithographic processes can operate as maskless processes, which can aid in reducing fabrication times and costs.

### 3D Lithographic Processes for Fabricating Compliant Contacts

A patterning additive manufacturing process or lithography process can be used to fabricate scaffolds for the compliant contacts. The processes can yield complex 3D structures of various geometries that are compliant. Advances in such processes and instrumentation make it possible to achieve highly parallelized, low-temperature processes, which, as described herein, can be used for the selective metallization of polymers. The polymers can be patterned by selective light exposure to polymerize or cross-link a layer of photoresist.

In lithography using negative resist, light, typically in the ultraviolet (UV) range, is absorbed by a photoinitiator molecule, which excites the molecule from a ground state to an excited state. From there, radical formation can occur through homolytic cleavage (e.g., Type I photoinitiators) or hydrogen abstraction (e.g., Type II photoinitiators), which can then lead to cross-linking reactions. Thus, light exposure facilitates a chemical reaction that results in the formation of a cross-linked polymer within the irradiated region. Developer can then dissolve and remove unexposed resist. Use of positive resist involves rendering exposed portions more soluble in developer, such that exposed portions of resist.

Conventional lithography processes produce a two-dimensional (2D) pattern that can be transferred to a surface of a substrate with direct writing or with implementation of a mask. Forming a 3D pattern using conventional lithography involves layering multiple 2D patterns, and thus involves multiple expensive lithographic sequences, and also limits the type of 3D patterns that can be produced.

In contrast, 3D lithography processes (e.g., interference lithography, microstereolithography, multi-photon lithography processes, one-plus-one photon lithography, light-sheet 3D printing, continuous liquid interface printing, and tomographic volumetric additive manufacturing) are able to localize photopolymerization or cross-linking within a specific point or points in three dimensions along the light path in the photoresist. In some variants of 3D lithography, chemical and optical non-linearities can be used to define structures with a feature size below the diffraction limit intrinsic to the light source. For example, in lithography processes implementing multi-photon polymerization (MPP), photon absorption occurs within the focal spot of the laser beam, which yields a more precise structure formation with smaller feature sizes than would be achieved with processes utilizing single-photon lithography, such as microstereolithography. Micron-scale or even nano-scale features can be obtained, and 3D structures like micropillars, nanopillars, complex, micron-scale lattice structures, micro-optics, and more can be fabricated in a single patterning process.

An optical set-up for microstereolithography (SL), a 3D form of single photon lithography (SPL), can generally include a laser, beam-steering optics, and focusing elements. For example, the laser can be selected to produce light at wavelengths in the ultraviolet (UV) range, such as 355 nm or 405 nm, corresponding to absorption peaks of common photoinitiators. In some cases, the laser can be continuous wave (e.g., CW) or pulsed (e.g., a Q-switched laser). The light generated from the laser is propagated along an optical path through elements like a beam expander, galvanometer mirrors (e.g., galvo scanners), telecentric optics (e.g., f-theta lenses), and any other suitable optical components. In some implementations, the optical path includes a digital micromirror device (DMD) or liquid crystal display (LCD) to enable projection-based layer curing rather than point-by-point vector scanning. The photosensitive resin is typically positioned on a build platform that translates vertically (e.g., a z-stage) to enable sequential layer formation, with each layer polymerized at or near the resin surface through single-photon absorption.

An optical set-up for maskless, multi-material, multi-photon lithography (MPL) can generally include a laser, directing and light-shaping optics, and an objective (e.g., a high numerical aperture (NA) objective). For example, the laser can be selected to produce light at wavelengths, such as ultraviolet (UV), green, red, and infrared (IR). In some cases, the laser can be continuous (e.g., CW) or pulsed (e.g., a femtosecond-pulsed laser). The light generated from the laser is propagated along an optical path through elements like an acousto-optic modulator (AOM), an acousto-optic deflector (AOD), a digital micromirror device (DMD), collimators, 4f optics, a spatial light modulator (SLM), an objective (e.g., 100×, 1.2 NA objective), and any other suitable optical components. In some cases, a portion of the optical path is parallelized to facilitate providing a plurality of laser beams to the sample (e.g., the photosensitive resin) that can simultaneously proceed with MPL.

As described herein, additive manufacturing processes, including 3D lithography or patterning processes, can precisely fabricate scaffolds (e.g., about monolithic structures, lattices, etc.) having specific geometries to satisfy engineering constraints for functionality to produce compliant contacts for sockets or testing (e.g., probe card contacts), which can have feature sizes on the order of nanometers to centimeters. The compliant contacts can have Z-dimensions between about 0.1 mm and 10 mm, or such as between about 0.1 mm and 0.2 mm, or about 0.4 mm and 4 mm, or about 0.3 mm and 0.6 mm, or about 3 mm and 5 mm. The compliant contacts can also have widths or XY-dimensions that are between about 50% and 90%, such as about 75% of the pitch of the contacts. For example, compliant contacts (e.g., spring pins) for sockets for IC dies can have widths that are at least about 500 μm and probes for wafer testing can have widths that are at least about 10 μm. The tips of the compliant contacts can be even smaller than the widths or diameters of the compliant contacts. For example, if a compliant contact has a width or diameter that is about 80 μm, the tip can be between about 20 μm and 30 μm. The scaffold for each part of the compliant contact can be provided by a single template element (e.g., polymer), or by multiple intersecting template elements, which in turn can be coated to produce the desired part. In some cases, the scaffold can be removed after at least some of the coating process has been completed, and the remaining space left unfilled or refilled. In some cases, the scaffold can remain in the final structure. In some cases, the amount of scaffold material (e.g., polymer) within the final structure, relative to the coating material, can be engineered for the part's purpose. For example, conductive features of the compliant contacts described herein can be engineered to minimize the final amount of the template material relative to metal coating to facilitate defining a given volume of material that may yield a certain level of electrical conductivity of the compliant contacts. On the other hand, the design of parts for purposes other than conductivity (e.g., compliance or mechanical support) can provide different patterns of the template material such that the post-patterning processes (e.g., metal coating, any template removal processes) can leave different proportions of the template material.

### Compliant Contacts Formed With 3D Lithography

Three-dimensional (3D) compliant contacts for microelectronic devices (e.g., contact probe cards, probe cards, test contact devices, test sockets, sockets for reversibly integrating microelectronics into larger systems like packages or boards, etc.) and fabrication processes for such compliant contacts are described herein. Although the embodiments described herein are largely described in the context of microelectronic testing devices (e.g., probe cards or test sockets), this is by way of example and should not be limited only to implementation in such testing devices. The contacts and the corresponding devices can generally entail compliant contacts for microelectronic devices. The contacts may be referred to as compliant contacts to be used in probe cards, test sockets, or other sockets, etc. In some cases, the contacts may be implemented in test sockets for final testing or burn-in of dies or other microelectronic elements, and the contacts may be implemented in probe cards for testing of wafers or panels.

The compliant contacts utilize a scaffold formed with a 3D lithographic process, which is then coated. The coating can be with a conductive material (e.g., metallic material). The scaffold can be a substantially unified structure (e.g., an approximately monolithic structure or an about unitary structure) that serves as the basis for the final structure of the compliant contact. In some cases, the scaffold can include multiple elements (e.g., template elements) or beams (e.g., dielectric beams, template beams, etc.), in which the scaffold elements are interconnected to form macrostructures, such as lattices. The conductive material is deposited over outer surfaces of such a multi-element scaffold until a desired volumetric fill fraction is achieved. In some cases, where the feature formed by metallization carries all or a majority of the current during operation, the coating on the outer surfaces can merge, yielding a substantially solid 3D structure. In some cases, where the feature formed provides compliance (whether or not carrying all or a majority of the current during operation), gaps remain after deposition to provide the compliant shape. In some cases, the scaffold remains in the final compliant contact. In some cases, the scaffold can be removed, leaving voids. In such cases, the voids can be at least partially refilled with a material that is the same as the material that was used in the deposition process, or it can be refilled with a different material.

3D lithography or any other processes or techniques capable of similar additive manufacturing processes (e.g., projection microstereolithography (PuSL), interference lithography, microstereolithography, multi-photon lithography processes, one-plus-one photon lithography, light-sheet 3D printing, continuous liquid interface printing, and tomographic volumetric additive manufacturing) can be implemented to create a scaffold comprising a dielectric material or a polymer, such as polymerized resin, which can subsequently undergo a deposition process where a structural material can be deposited conformally over the surfaces of the scaffold. At least for features meant to carry current for the compliant contacts described herein, the structural material is electrically conductive and typically metal. The conductive material grows outwardly from the surfaces of insulating scaffold material. In some instances, the conductive material is selectively deposited onto the scaffolding material without depositing on other exposed structures (e.g., substrate between contact pads) or depositing on those other structures at a much lower rate.

In some embodiments, a compliant contact scaffold or framework can be formed over the carrier or substrate, such that the scaffold couples to or is formed on and extends from at least a portion of a plurality of conductive features in or on the carrier or substrate. The plurality of conductive features can be a plurality of contact pads (e.g., conductive contact pads). In some cases, the substrate remains as a part of the final structure or device (e.g., socket or probe card). In some cases, the carrier or substrate can be attached (e.g., soldered, direct bonded, etc.) to another larger substrate to form the device (e.g., a system substrate, a reconstituted structure, or a larger die/wafer, etc.). In some cases, the substrate or carrier can be removed, leaving behind the plurality of conductive contacts or conductive contact pads to which a scaffold or framework is connected. In some cases, rather than being grown on the contact pads of the substrate or carrier of the microelectronic device (electrically interfacing device), the compliant contacts can be formed separately and removed from another carrier or substrate for a pick-and-place procedure. Processes described herein, however, are particularly conducive to forming and transferring multiple compliant contacts simultaneously, considerably reducing time and costs for manufacture.

The scaffold can comprise an approximately monolithic structure, or an elongate structure (e.g., a compliant contact having a primary elongate structure surrounded by secondary spring-like elongate structures), or a plurality of struts of a template material (e.g., dielectric beam, or beams of polymerized photoresist or crosslinked polymer). In some cases, the scaffold comprises a compliant configuration. For example, a polymer scaffold that is uncoated can have an elastic modulus between about 100 MPa and 10 GPa. In some embodiments, the scaffold material can be any material definable in three dimensions at the scales discussed herein, such as by electrochemical additive manufacturing, liquid metal extrusion, centering based processing, etc. In some cases, the scaffold is selectively coated with the conductive material (e.g., selectively metallized). In some cases, multiple different materials coat the scaffold.

In some cases, the scaffold can include a contact structure having support structures, which can be formed to surround and/or mechanically connect with the conductive features of the compliant contacts for added support. Such support structures, which can also be compliant (particularly if linked to the internal compliant structures), can serve to introduce rigidity and resistance to lateral loads during operation, can help mitigate sagging and other deformations that might occur to the compliant contact scaffold structures during the fabrication process, and/or prevent short circuits between adjacent compliant contacts. The polymer scaffold material of the support structures (or other structure on which metallization is not desired) can be surface treated to chemically differentiate it from the scaffold of the parts meant to carry current, or can be masked during the metallization process. A selective metallization process can be implemented following formation of the compliant contact scaffold structures and support structures, such that the compliant contact features are metallized and other structures are not. The final compliant contact (e.g., probe) can comprise a conductive material, particularly metal, with a dielectric (e.g., polymer) core, which can then be used for electrical interfacing with (e.g., testing of) microelectronic devices or semiconductor devices. Any metal left in regions where metal is not desired can be removed after deposition by brief isometric etching of metal to remove thinner metal from regions with slower deposition, or by lift-off of any mask used to cover such regions.

In some cases, the material of the scaffold can remain embedded in the deposited material or can be removed during or after the coating process. If removed, voids left by the removal can be refilled with the same material deposited by the coating process, or by a different material, or the voids (representing a minority volume of 3D structure) can remain in the final structure. In some cases, where the fabrication process implements physical vapor deposition (PVD) or chemical vapor deposition (CVD), gaseous or vacuous voids can remain. These voids may be desired or beneficial for tuning the structure's mechanical (compliance, strength) and electrical properties. In some cases, the compliant contact comprises an elastic modulus between about 50 MPa and 200 GPa, between about 100 MPa and 200 GPa, between about 50 MPa and 150 GPa, or between about 10 GPa and 150 GPa. In some cases, a compliant contact having a scaffold that has been coated with a conductive material can have an elastic modulus between about 10 GPa and 150 GPa. In some cases, the compliant contact comprises a failure strain between about 5% and 15%.

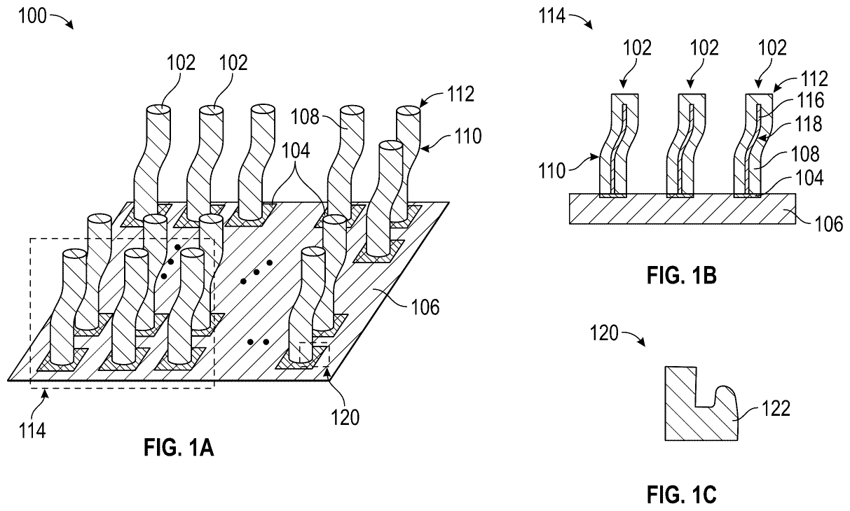

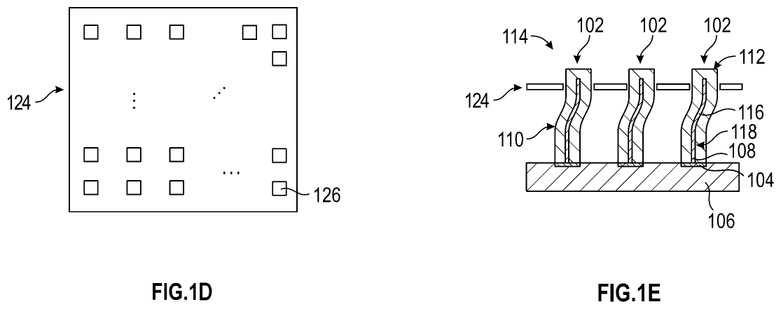

FIGS. 1A-1E are schematics illustrating a microelectronic device 100 (e.g., a microelectronic testing device) formed with 3D lithography, according to one embodiment. The microelectronic device 100, as shown in FIG. 1A, can include a plurality of compliant contacts 102 (e.g., probes) formed on a plurality of contact pads 104 that are in or on a carrier or substrate 106. In some cases, the substrate 106 is provided with exposed contact pads 104 formed of a conductive material, typically metal. The substrate 106 can be any of a variety of materials, such as silicon (Si), glass, ceramic, etc., but for probe card and test socket embodiments is typically an organic substrate such as a conventional printed circuit board (PCB). In some cases, the microelectronic device 100 can be configured to work with standard wafer-probe equipment, burn-in boards, or specialized load boards with minimal changes.

The contact pads 104 can comprise copper (Cu), aluminum (Al), gold (Au), silver (Ag), cobalt (Co), ruthenium (Ru), molybdenum (Mo), or any other suitable conductor. FIG. 1A shows an approximately rectilinear and periodic arrangement of the contact pads 104. In some cases, the contact pads 104 can be arranged to have a periodic configuration or can have a non-uniform arrangement. The pitch of the contact pads 104 can be customized based on the intended application of the microelectronic device 100. For example, the pitch can be between approximately 400 nm and 1000 μm, such as 3 μm, 25 μm, 150 μm or 935 μm. In some cases, the pitch can be in a range between about 10 μm and 400 μm, such as about 36 μm, 45 μm, 80 μm, and 120 μm. In some cases, the diameters of the conductive contact pads 104 can be between approximately 300 nm and 600 μm, or between 300 nm and 150 μm, or between approximately 2 μm and 60 μm. In some cases, the compliant contacts have dimensions suitable for making contact with a microelectronics device to be interfaced and having various contact pad dimensions. For example, contact pads in microelectronic devices for hybrid bonding can have dimensions between about 1 μm and 5 μm. Contact pads in microelectronic devices upon which micro-bumps are formed can have dimensions between about 5 μm and 25 μm. Contact pads in microelectronic devices for flip-chip bumps can have dimensions between about 20 μm and 60 μm. Contact pads in microelectronic devices for substrate ball/pad formation can have dimensions between about 60 μm and 150 μm. Contact pads in microelectronic devices that are PCB BGA pads can have dimensions between about 250 μm and 600 μm. In some cases, the diameters or widths of the conductive contact pads 104 in the microelectronic device 100 can have dimensions similar to those of the contact pads in the microelectronics device to be interfaced.

In some embodiments, an adhesion layer or a seed layer can be deposited or formed over or on the contact pads 104. The inclusion of an adhesion layer or a seed layer over the contact pads 104 can facilitate electrical coupling between a conductive material 108 that forms the outer surface 110 of a compliant contact 102 and a contact pad 104. In some cases, the adhesion or seed layer can include titanium (Ti), chromium (Cr), or nickel (Ni).

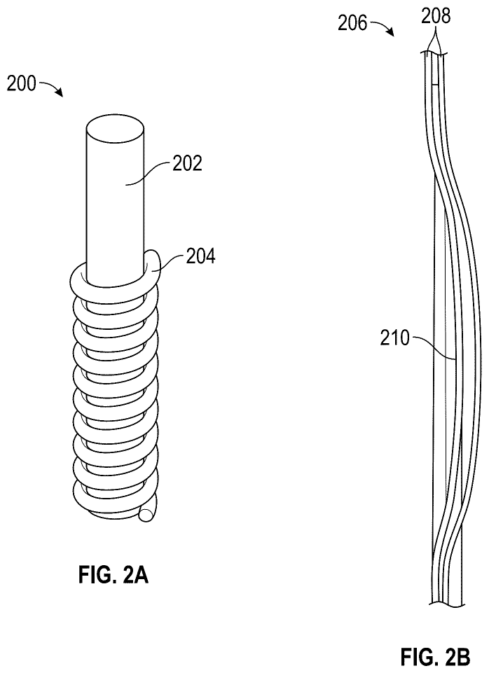

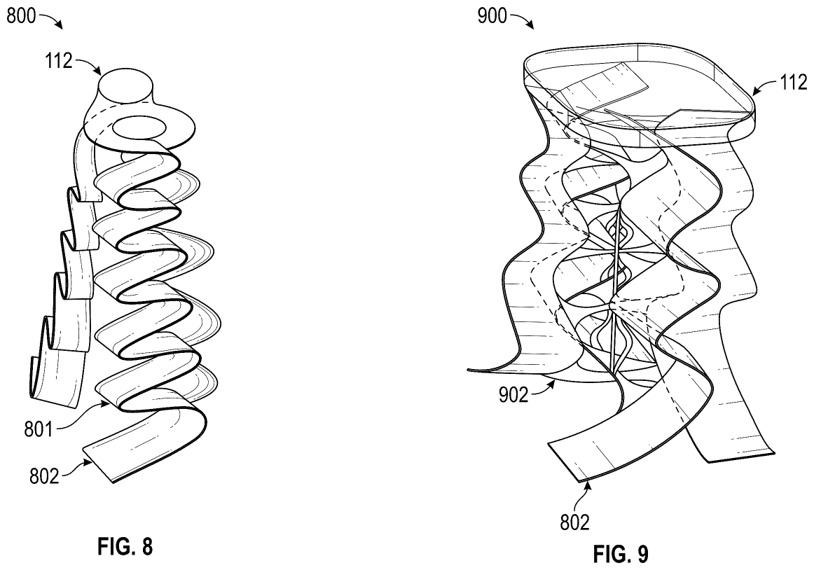

The compliant contacts 102 can be formed directly onto the contact pads 104 of the substrate 106 and their surfaces are formed of a conductive material as a result of a controlled deposition process (e.g., a controlled metallization process). In some cases, the compliant contacts 102 can be formed over the contact pads 104, and one or more intervening layers can exist between the compliant contacts 102 and the contact pads 104 (e.g., an adhesion or seed layer). The compliant contacts 102 are designed and configured to be compliant structures under vertical load, facilitating adequate electrical connections to a an electrically interfacing device (e.g., a device-under-test (DUT)), accommodating surfaces to be contacted that have irregularities (e.g., non-planar surfaces), and mitigating or decreasing the likelihood of damage to the electrical components to be electrically interfaced with. By tuning the geometry of the compliant contacts 102, the compliant contacts 102 can possess relatively low effective spring constants on-axis and high resistance to large lateral deflections, which can enable high bandwidth. Various properties of the compliant contacts 102 can be tuned, including strength, compliance, and resistance, by adjusting or specially designing the shape of the compliant contact 102, adjusting the thickness of the deposited material, etc. In some cases, other parameters of the compliant contacts 102 that can be tuned can include a helix diameter (e.g., the diameters of the helices as shown in FIGS. 2A, 3D, 5, 6, 11, 12, 13, etc. could be adjusted), pitch, number of turns, ribbon thickness (e.g., the thickness of the ribbons as shown in FIGS. 8, 9, etc. could be adjusted), flexure width (e.g., the widths of the flexures as shown in FIGS. 2B, 7A-7B, 19, etc. could be adjusted), etc.

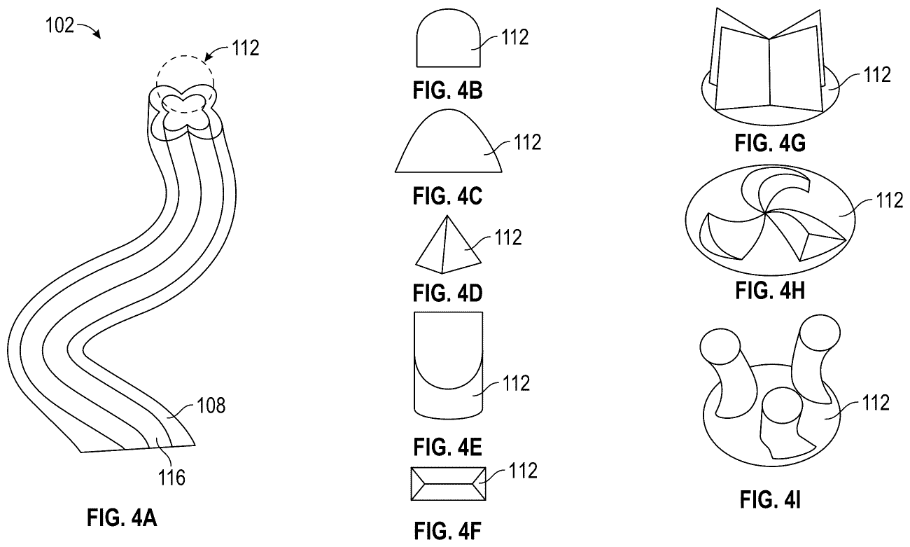

The compliant contacts 102 can be designed or configured to have a variety of geometries that are selected for specific applications. FIGS. 1A and 1B illustrate vertical compliant contacts that are compliant, vertically elongate flexures. In some cases, the compliant contacts 102 can have Z-dimensions (e.g., vertical heights) between about 0.1 mm and 10 mm, such as between about 0.1 mm and 0.2 mm, or about 0.4 mm and 4 mm, or about 0.3 mm and 0.6 mm, or about 3 mm and 5 mm. The compliant contacts 102 can also have widths or XY-dimensions that are between about 50% and 90%, such as about 75% of the pitch of the compliant contacts 102. In some cases, and as described herein, the compliant contacts 102 can comprise helical springs, flexural arrays, configurations having internal and external supports, and metamaterials. In some cases, the compliant contacts 102 can comprise simple buckling beam structures, as shown. A compliant contact 102 can also have a tip 112 which engages or makes electrical contact with an electrically interfacing device, such as a DUT. In some cases, the tips 112 can be even smaller than the widths or diameters of the compliant contacts 102. For example, if a compliant contact 102 has a width or diameter that is about 80 μm, the tip 112 can be between about 20 μm and 30 μm. In some cases, the tip 112 is formed with and is a part of the compliant contact 102. FIGS. 1A and 1B show the tip 112 as having a flat shape (e.g., a flat tip). In some cases, and as described herein, the tip 112 design can include screw or helical crowns, multi-tipped or spiked tips, and self-locating geometries. See, for example, FIGS. 4B-4I and attendant description.

The microelectronic device 100 is scalable. In some embodiments, the microelectronic device 100 can include arrays of compliant contacts 102. These arrays can vary in size from a few compliant contacts (or probes) to millions (or more) on a single substrate.

FIG. 1B is a cross-sectional view of a portion 114 of the microelectronic device 100 in FIG. 1A. As shown in FIG. 1B, a compliant contact 102 can include a scaffold 116 that is coated with a conductive material 108. The fabrication process utilizes a 3D lithographic process that is followed by a coating or deposition process. For example, the substrate 106 with exposed contact pads 104 is provided or obtained. A photosensitive material is applied across the substrate 106. For example, the photosensitive material can include a multiphoton-sensitive resin (e.g., epoxy-based, acrylate-based, or hybrid organic/inorganic). The thickness of the photosensitive material can be in a range on the order of micrometers to millimeters or more, depending on the desired height of the final contact 102.

A light-based system can then be used to modify the photosensitive material, forming polymeric or dielectric scaffolds 116. For example, a 3D lithographic system including a laser system can be implemented to direct-write 3D structures within the photosensitive material (e.g., resin). In some embodiments, alternative polymer resins or metal alloys (e.g., platinum-group metals for high-temperature testing) can be implemented. In some embodiments, biocompatible coatings can be implemented for specialized sensor applications. In some cases, the laser system facilitates multiphoton or two-photon lithography. By precisely tuning or controlling the parameters of the laser system, including laser power, scan speed, and z-height, the desired geometry (e.g., dimensions, shape for desired compliance, such as curvature, coils, flexures, fluidic channels) of the compliant contact 102 can be achieved. Following the formation of the scaffold 116, unmodified or unexposed photosensitive material can be removed. For example, the substrate 106 with the formed scaffolds 116 can be immersed in a developer to remove unpolymerized resin, which leaves behind and reveals intricate 3D scaffolds. A post-exposure bake or a UV cure can be implemented to finalize any polymer crosslinking and enhance mechanical stability in the scaffolds 116.

The scaffolds 116 subsequently undergo a coating process, where a conductive coating is deposited or formed over the surfaces 118 of the scaffolds 116. Each scaffold 116 and the conductive coating or conductive material 108 together make up what may be referred to as the body of the compliant contact 102. As described herein, the body can comprise multiple components (e.g., a core surrounded by a spring, a spring, an internal or external support structure mechanically coupled to a plurality of flexural elements, etc.). In some cases, and as described herein, the scaffold 116 can be removed, such that only the deposited materials (e.g., the conductive coating) remain. In such cases, this structure may also be referred to as a body of the compliant contact 102.

Various approaches, including atomic layer deposition (ALD), sputtering or evaporation, electroless plating, electroplating, etc. can be implemented for the metal deposition. ALD can form conformal seed layers (e.g., titanium nitride (TiN), Ti, Al, etc.). Sputtering or evaporation can be used to form thin metal films. Electroless plating can be implemented to form Ni, Cu, or other metals as a seed layer. Electroplating can build up thicker conductive (e.g., metal) layers (e.g., tens of microns, such as between about 1 μm and 50 μm, between about 1 μm and 10 μm, or between about 5 μm and 50 μm, such as about 20 μm) to enable high current capacities. In some embodiments, selective coating of the conductive material (e.g., selective metallization) over the scaffold 116 is desired. In some cases, the selective metallization can be achieved through depositing through a shadow mask or by masking (e.g., with photoresist) areas that are not to be metallized, shielding areas not to be coated with a conductive material. In some embodiments, any conductive material (e.g., metal) over undesired areas can be removed by lift-off processing during removal of the mask, leaving behind precisely metallized probe or compliant contact structures.

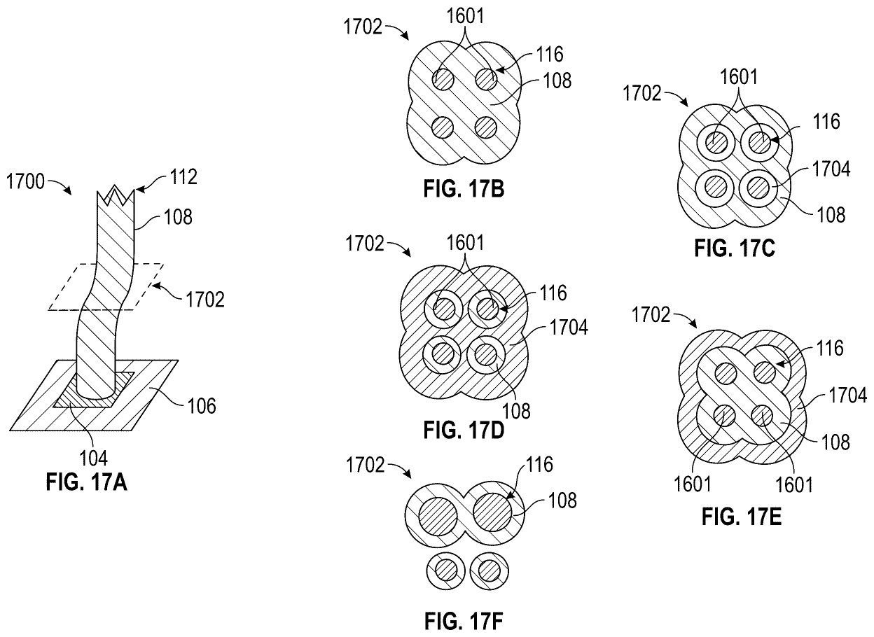

In some embodiments, more than one coating material can be deposited over the scaffold 116. For example, the compliant contact 102 can include a conductive material 108 and an additional material (see FIGS. 17A-17E and attendant description). In some cases, the additional material is between the scaffold 116 and the conductive material 108. In some cases, the additional material may be deposited over or directly onto the conductive material 116. The additional material can be selected to be electrically conductive and have different mechanical properties from the conductive material 108. The additional material can be selected to tune the overall strength, stiffness or flexibility of the compliant contact 102. For example, a compliant contact scaffold 116 can have a Cu layer initially deposited followed by deposition of a Ni layer. The Ni layer could define the outermost surface of the compliant contact 102, and might be desired for being harder/more durable than Cu, which can allow for increased structural integrity and hardness for piercing native oxide on the contact pads of an electrically interfacing device (e.g., DUT). In some cases, the conductive material 108 and/or the additional material can comprise Cu, silver (Ag), gold (Au), tungsten (W), platinum (Pt), palladium (Pd), cobalt (Co), ruthenium (Ru), titanium (Ti), titanium nitride (TiN), or alloys of any of these. Because the additional material can be selected for tuning mechanical rather than electrical properties, it can be an insulating material in some cases.

In some embodiments, alternate masking approaches can be implemented in the fabrication process of the compliant contacts 102 to facilitate defining conductive regions. These approaches can include traditional 2D photolithography, inkjet printing of seed layers, selective photo or thermal-induced entrainment of seed materials for metal coating and laser direct-write photoreductive metallization.

In some embodiments, the scaffold 116 remains embedded in the conductive material 108 in the compliant contact 102, and can represent less than 50% of the volume of the compliant contact 102, such as between about 0.001% and 25% of the volume. In some cases, the compliant contact 102 can have between about a 50% and a 100% metal composition, such as between about 70% and 99.999% metal composition by volume or weight. In some embodiments, during the deposition process or after, the scaffold 116 can be removed using techniques such as wet etching or isotropic dry etching. Masking can be used to create inlets and outlets for the mass transport of the scaffold 116 to be removed. In some cases, the compliant contact 102 can then maintain these voids (e.g., filled with air) created by the removal of the scaffold 116 or can be filled through additional deposition techniques (e.g., a same or a different material as compared to the conductive material 108) to tune desired mechanical and/or electrical properties of the compliant contact 102.

In some embodiments, one or more artifacts may exist as a result of the 3D lithographic and/or coating (or metallization) processes. In some cases, the artifacts can include voids or a surface roughness (e.g., a surface texture) that can be indicative of the lithographic and/or the coating processes, and such artifacts can exist whether or not the final compliant contact structure includes the scaffold. For example, an outer surface of a compliant contact, which is defined at least in part by the deposition of a coating, such as a metallic material, may have a non-smooth surface that is an artifact of the fabrication process. In some cases, the surface roughness can be in a range between about 100 nm RMS and 800 nm RMS, such as between about 100 nm RMS and 500 nm RMS, or such as between about 200 nm RMS and 800 nm RMS. In another example, the compliant contact may include a grain pattern that is indicative of the deposition of a coating, such as a metallic coating, over a scaffold, whether the scaffold remains or is removed from the final structure. In such instances, it is possible that the coating has columnar grains that are normal to the surface on which it is grown. In another example, the scaffold can be removed, such that the final compliant contact structure includes the coating or conductive material and voids in place of the scaffold. In such cases, the remaining conductive coating includes accessible voids and/or additional holes to allow etchant access and to allow decomposition byproducts to escape from inside of the compliant contact structure. In some cases, the implementation of such accessible voids and/or holes can yield one or more artifacts that are discernible in the final product. These artifacts can include patterns of voids related to the scaffold and spatially varying material composition.

The compliant contacts 102 are designed and fabricated so that they are compliant. A measure of the compliancy includes stiffness (e.g., resistance of the contacts to deformation), compliance (e.g., the inverse of stiffness), etc. For example, the compliant contacts 102 can have a stiffness in a range between about 0.5 gram-force (gf) per 100 μm and 2 gf per 100 μm, such as about 1 gf per 100 μm, which corresponds to a range of compliance values between about 0.005 cm/gf and 0.02 cm/gf, such as about 0.01 cm/gf. The compliant contacts 102 also have high current carrying capacity. The maximum amount of electric current that a compliant contact 102 can carry will depend on various parameters like the width (or diameter) of the compliant contact 102, thickness of the deposited metal, and the length of the compliant contact 102. In some cases, the maximum amount of electric current that a compliant contact 102 can carry can be in a range between approximately 0.3 A and 10 A, such as between about 0.6 A and 3 A. In some cases, the compliant contact 102 can have resistance values in a range between about 0.01 Ω and 1 Ω, or between about 0.05 Ω and 1 Ω. In some cases, the compliant contact 102 can have a resistivity value in a range between about 1.6 μΩ·cm and 50 μΩ·cm.

FIG. 1C shows a magnified view of a base portion 120 of a compliant contact 102. In some embodiments, and as shown in FIG. 1C, a foot-like structure 122 can be fabricated at the base of a compliant contact 102 and shielded from metal deposition (e.g., by the same mask that prevents deposition on the substrate 106 between contact pads 104), leaving an exposed polymer for offgassing purposes. For example, the foot-like structure 122 can allow for isotropic dry or wet etches to access encapsulated polymer that might otherwise be inaccessible.

In some cases, the microelectronic device 100 can include one or more guide plates 124. FIG. 1D schematically illustrates one guide plate 124 having a plurality of holes 126. A skilled artisan would understand that guide plates, such as the illustrated guide plate 124, are known in the art and are implemented to fix compliant contacts contact in place, to support them and provide them with appropriate boundary conditions. Such guide plates 124 can be implemented for buckling beam probes, which may be more than 1.0 mm in length, and therefore more subject to collapsing or shorting with adjacent contacts. These guide plates 124 can be between about 100 μm and 1000 μm thick, such as about 250 μm thick, and typically comprise a ceramic material with a plurality of holes throughout (e.g., laser-formed holes). As shown in FIG. 1E, the compliant contacts are threaded through the holes of the guide plate 124, and the guide plate 124 would remain in the final device product. In some embodiments, a guide plate 124 can be disposed on or over a substrate 106 comprising contact pads, and the compliant contacts 102 can be formed through the holes 126 of the guide plate 124 and on or over the contact pads 104. Following fabrication of the compliant contacts 102, the guide plate 124 can be raised to its final supporting position. Generally, one guide plate may be implemented and fixed with respect to the compliant contacts, and a second may be implemented to provide a further boundary condition on the compliant contacts. Regardless of whether one or two or more guide plates are implemented, each guide plate is fixed with respect to the substrate.

FIGS. 2A-2B illustrate different possible configurations of a compliant contact, according to one embodiment. Unless otherwise noted, the fabrication processes, materials, and alternatives described herein and with respect to FIGS. 1A-1E are applicable to the compliant contact structures described in FIGS. 2A-2B.

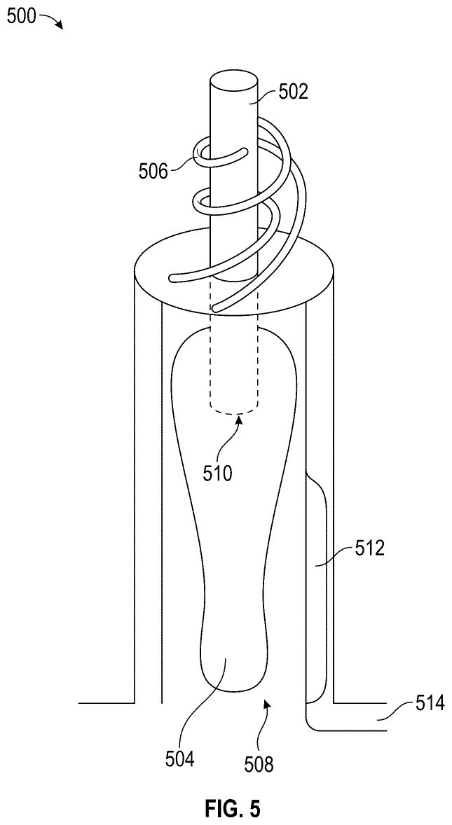

FIG. 2A is a compliant contact 200 having a primary elongate structure or core 202 surrounded by a secondary structure or coil structure 204 or spring. The core 202 serves as the primary electrical conductor for the compliant contact 200. In some cases, the compliant contact 200 can decouple the design and composition of the core 202 (e.g., electrical contact or plunger chosen for conductivity) from the design and composition of the coil structure 204 (e.g., spring chosen for compliance), which can allow for the fabrication of substantially shorter compliant contacts 200 for a desired amount of overtravel (OT). For example, for a typical OT specification of 50 μm to 250 μm, the compliant contact 200 can have a vertical height that is between about 200 μm and 500 μm, such as about 400 μm. In contrast, compliant contacts or probes like the buckling beam probes (e.g., vertical beam probes) can be substantially longer for the same OT specification, such as about 4 mm in height. Thus, in some cases, the compliant contact 200 can have a height or length that is approximately 1/10^{th} the height or length of a buckling beam probe for a given OT specification. With a shorter compliant contact, like the compliant contact 200 of FIG. 2A, an approximately 2× current carrying capacity can be achieved as compared to a buckling beam probe. Additionally, shorter compliant contacts can reduce the number of guide plates to be used with a microelectronic device, owing in part to the greater lateral stiffness of such probes. For example, no guide plates may be implemented, or one guide plate may be implemented with the microelectronic device. Further, the coil structure 204 (or spring section) of the contact 200 can be tailored to include multiple, nested or parallel coils or helical wires. These parallel members can simultaneously accommodate the deformation of the contact 200 while allowing for a decrease in stress and force due to the decreased area and corresponding moments of inertia (e.g., bending or polar moments of inertia). With these characteristics, shorter compliant contact can be achieved with higher current and thermal carrying capacities. In some cases, the core 202 of the compliant contact 200 can have a width or diameter that is between approximately 10 μm and 100 μm, such as about 15 μm, or 40 μm, or 60 μm. The core 202 and coil structure 204 can take any of a variety of forms for ensuring both the ability to deform to provide the desired OT, as well as continuous conductivity through the compliant contact 200 in operation. See, for example, FIGS. 5, 11, 12, and 20-21B and attendant description. In some embodiments, some features of the compliant contacts 200 need not be conductive. For example, in the compliant contacts 200, the core 202 can be conductive and the spring could be non-conductive. Thus, non-conductive coatings can be used for various features of the compliant contacts to meet certain needs (e.g., strength, compliance, ductility).

FIG. 2B illustrates a compliant contact structure, according to another embodiment. In FIG. 2B, a compliant contact 206 has a structural support 210 (or a single beam) surrounded by and mechanically coupled to two compliant flexures 208 (e.g., two beams). In some cases, the support 210 is a lithographed beam comprising a polymer with a conductive (e.g., metallic) coating over the polymer. The two compliant flexures 208 are slender beams, as shown, but can alternatively be ribbons or curved struts that are arranged about the support 210 to provide enhanced compliance and lateral load resistance for the compliant contact 206. In some cases, a spacing between the two compliant flexures 208 can be in a range between about 1 μm and 20 μm, such as about 3 μm. In some cases, a compliant flexure 208 can have a width or a diameter in a range between about 15 μm and 60 μm, such as about 35 μm. Although two compliant flexures 208 are illustrated, in some cases, more than two compliant flexures can be implemented. In some cases, flexures, springs, and/or beams can be mutually connected by additional compliant supporting structures, such as struts or trusses, either internally or externally (similar to DNA's double helix internal cross-members) to introduce rigidity and resistance to lateral load.

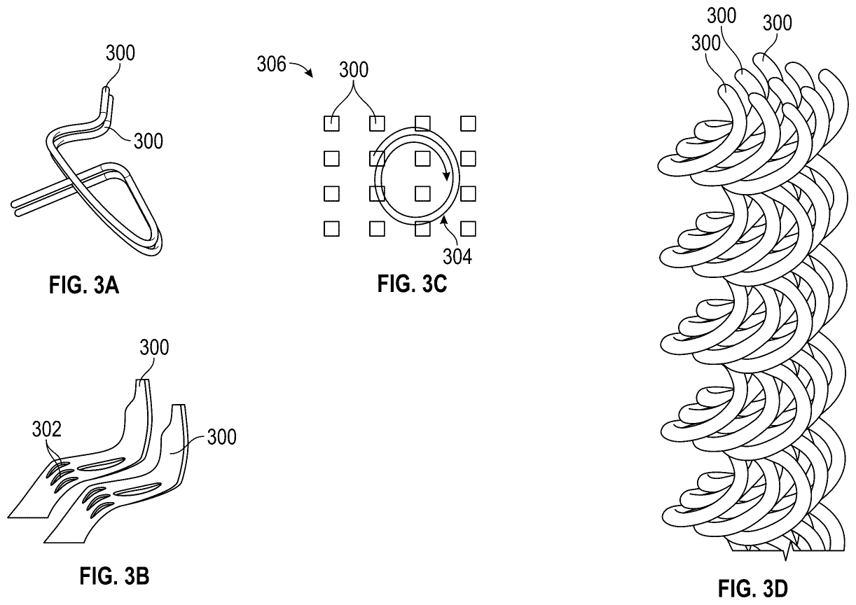

FIGS. 3A-3D illustrate possible configurations of compliant contacts 300 having nested configurations, according to one embodiment. Unless otherwise noted, the fabrication processes, materials, and alternatives described herein and with respect to FIGS. 1A-1E are applicable to the compliant contact structures 300 described in FIGS. 3A-3D.

In some cases, a dense array of coils or coil-like structures for compliant contacts or probes may be desired (e.g., 1 coil per 900 μm²), depending on the electrically interfacing device (such as a DUT) for which the compliant contacts and/or the microelectronic device is being designed. To accommodate this configuration, the compliant contacts can be arranged in a nesting configuration or weaved together. For example, compliant contacts 300 corresponding to nesting structures in a 3D space can be implemented as shown in FIG. 3A. In some cases, the probes or compliant contacts 300 are interweaved such that when they are compressed together, as in normal operation, the contacts 300 do not contact each other. In some cases, the compliant contacts 300 can include nesting buckling beam geometries (2D), as shown in FIG. 3B. FIG. 3B further illustrates exotic nesting buckling beam compliant contacts 300, which can be designed using artificial intelligence prior to lithographic fabrication. The design can include intentionally formed voids 302 or empty segments within each of the compliant contacts 300, which may impart certain compliant characteristics for the compliant contacts 300, while balancing the desired conductivity.

Implementation of a nesting configuration can yield a common 3D sweep path 304 that is shared across the compliant contacts 300, as shown in FIG. 3C. With a common 3D sweep path 304, the compliant contacts 300 do not intersect or interfere with other compliant contacts upon compression of the compliant contacts 300. Thus, the individual compliant contacts 300 are individually compressible, and they can be arranged such that they do not contact one another during simultaneous deflection over the desired OT, as is typical during microelectronics testing. Thus, the individual compliant contacts 300 can have lateral dimensions that define a footprint that overlaps with multiple contact pads (such as contact pads 104 in at least FIG. 1A) and overlaps with the footprint of other compliant contacts 300, and yet these compliant contacts 300 do not contact or interfere with one another. This permits greater design freedom to achieve the desired shape for the desired levels of both conductivity and compliance. FIG. 3C shows a cross-section 306 of an array of compliant contacts 300 having a shared 3D sweep path 304, such that all of the profiles of the compliant contacts 300 can be swept or extruded along a path that is normal to the substrate. In some cases, and as shown in FIG. 3D, the compliant contacts 300 can include nested helical structures or springs having a shared 3D sweep path. In such cases, the current path is along the path of the helix, rather than through a primary core structure. Although FIG. 3D illustrates nine compliant contacts 300, in some cases, a larger number of compliant contacts, such as on the order of hundreds or thousands or millions, could be implemented. As compared to a conventional 2D-patterned cantilever or beam design, a 3D-patterned helical spring of comparable wire diameter and footprint can exhibit significantly lower compressive force at a given deflection. This reduction in the contact force allows for an order of magnitude increase in feasible compliant contact density for a given fixed total load.

FIGS. 4A-4I illustrate a compliant contact 102 and various tips 112 for the compliant contact 102 that can be implemented. Unless otherwise noted, the fabrication processes, materials, and alternatives described herein and with respect to FIGS. 1A-1E are applicable to the compliant contact structure and tips 112 described in FIGS. 4A-4I.

3D printing or 3D lithographic processes can facilitate custom tip morphologies. For example, a wide array of tip geometries can be fabricated, such as self-locating tips, screw tips, multi-pronged tips, or helical crowns. Such tips can offer engineered alignment and/or scrub or rotational motion when under load or under compression to break through surface oxide or contamination layers on contact pads of an electrically interfacing device (e.g., DUT, etc.). Thus, with the advanced 3D printed tip morphologies, contact resistance is reduced, pad surface cleaning is facilitated, and stable electrical connections are made.

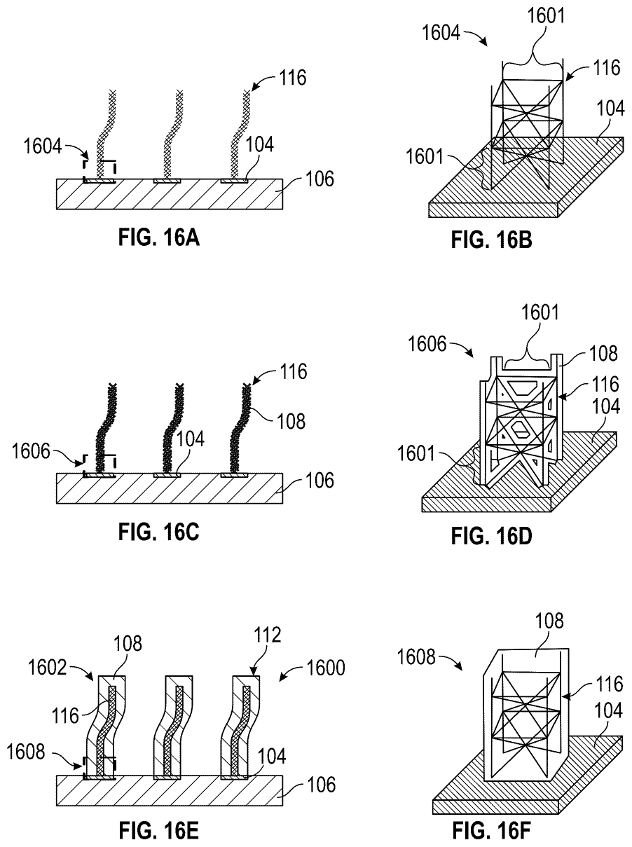

FIG. 4A is of a portion of a compliant contact 102 having a polymer or dielectric scaffold 116 that is surrounded by a conductive material 108 (e.g., metallized external structure) and a tip 112 (e.g., metallized tip, or tip coated with a conductive material). In some embodiments, the tip 112 can be dipped into an electroplating bath with rhodium to achieve a highly wear-resistant tip that does not affect the rest of the compliant contact properties. In some embodiments, directional or selective metallization can also be utilized to selectively metallize the tip 112. The presence of the scaffold 116 can be an indication that 3D lithography and subsequent metallization was employed to form the compliant contact 102, although other indications can be present for embodiments in which the scaffold 116 is removed and/or refilled, as described elsewhere herein (e.g., see the descriptions regarding FIGS. 1B and 16E-16F). In some cases, the tip 112 is also fabricated with a 3D lithographic process during the fabrication process of the rest of the compliant contact 102. The skilled artisan will understand that the tips 112 described below can be employed with any of the compliant contact structures described herein and are not limited to the simple curved structure illustrated in FIG. 4A.

FIGS. 4B-4I illustrate the different tip morphologies that can be achieved with a 3D lithographic process. It should be understood that the tip morphologies shown are provided as examples and are not to be limited to those that have been illustrated. FIG. 4B illustrates a tip 112 having a shape corresponding to a sphere. FIG. 4C illustrates a tip 112 having a shape corresponding to a hyperboloid. FIG. 4D illustrates a tip having a shape corresponding to a pyramid. FIG. 4E illustrates a tip having a shape corresponding to a wedge. FIG. 4F is a top view of the wedge-shaped tip 112 of FIG. 4E. FIG. 4G illustrates a tip having a shape corresponding to a crown or a multi-wedge. FIG. 4H illustrates a tip having a shape corresponding to a screw tip, and FIG. 4I illustrates a tip 112 having multiple contact protrusions, which can be compliant. Tips 112 that are screws or helical crowns (e.g., FIG. 4H) are advantageous because they can provide a self-cleaning, rotation scrub motion upon contact with the contacts of an electrically interfacing device. Tips 112 that are multi-tipped or spiked tips (e.g., FIGS. 4D and 4G) are beneficial because they can provide multiple contact points that can increase chances of piercing native oxides that have formed on the contacts of an electrically interfacing device, thereby establishing stable electrical contact without excessive force. The same motivation applies to tips 112 that have sharp terminations, such as FIGS. 4D-4F. The degree of compliance can reduce risk that such sharp terminations will excessively damage contact pads on the electrically interfacing device. In some cases, tips 112 can have self-locating geometries with multiple and/or sloping peaks (e.g., FIGS. 4G-4I). For example, tips 112 that are chamfered or funnel-like can guide themselves onto a DUT pad. Such tip self-locating tip geometries can also enable the tips to be attached to a hierarchical platform, as described herein, on which the compliant contacts 102 optionally sit, which enables alignment to the surface of an electrically interfacing device. In some cases, the tip can comprise a split tip (not shown), such as a tip having two electrically conductive portions (e.g., electrodes) that are electrically insulated from one another.

In some cases, a tip 112 can experience about 50 μm of wear over its lifetime, which can result in fine features being removed. The type of tip 112 that is selected for a compliant contact 102 can be selected based on how expensive the compliant contact 102 is to make and how much wear the tip 112 might experience at a particular rate. For example, test sockets, which are used for a final test or burn-in, may implement more intricate features because their applications result in less wear, and the test sockets themselves are relatively inexpensive to fabricate.

FIG. 5 illustrates an example of a compliant contact 500 having a core or a plunger 502 that plunges into a conductive fluid 504, like a liquid metal, and one or more guide flexures 506 or rails such as spiraling coils that surround the plunger, according to one embodiment. Unless otherwise noted, the fabrication processes, materials, and alternatives described herein and with respect to FIGS. 1A-4I are applicable to the compliant contact structure described in FIG. 5. In some cases, the compliant contact 500 can be described as a liquid metal reservoir compliant contact, which comprises a partially or fully enclosed 3D-printed chamber 508 containing a conductive fluid 504. A distal end 510 of the compliant contact 500 is suspended in or just above the conductive fluid 504, which can form an ultra-low-force electrical interface with an electrically interfacing device, such as a DUT. Conductive fluids 504 or liquid metals allow for simultaneous deformation of the compliant contact 500 and maintenance of electrical contact. The plunger 502 can move in the conductive fluid 504 and the spiraling coils or the one or more guide flexures 506 around the plunger 502 provide compliance for the desired OT while also constraining the direction and extent of movement for the plunger 502 and provide mechanical stiffness. The plunger 502 and the one or more guide flexures 506 are also attached to one another. In some cases, the compliant contact 500 can have a wetting internal geometry or structure. In some cases, one or more internal recesses 512 can be incorporated to take up excess volume. In some cases, a microfluidic inlet channel 514 cis formed to facilitate the filling of the 3D-printed chamber 508 with the conductive fluid 504. In such cases, an outlet may also be incorporated into the final structure of the compliant contact 500. In some cases, the 3D-printed chamber 508 can be filled with the conductive fluid 504 under vacuum. The guide flexures 506 and chamber 508 can include internal scaffold material (e.g., polymer formed by cross-linked resist) and can be metallized at the same time as the plunger 502, or can be coated with other structural materials using selective deposition techniques.

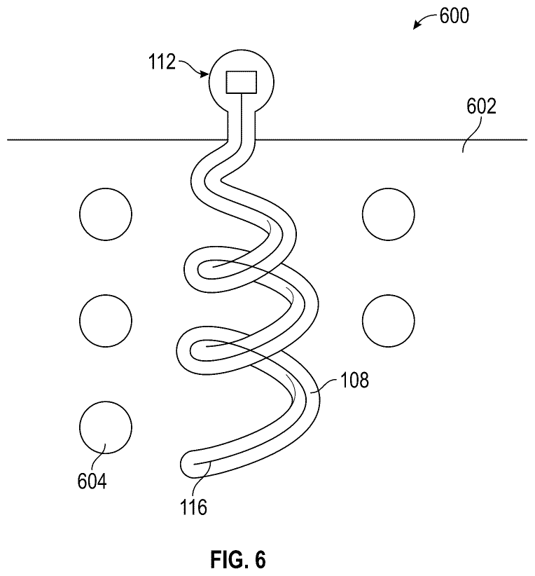

FIG. 6 illustrates one example of a compliant contact 600 at least partially embedded in a porous material 602, according to one embodiment. Unless otherwise noted, the fabrication processes, materials, and alternatives described herein and with respect to FIGS. 1A-4I are applicable to the compliant contact structure described in FIG. 6. In some cases, the compliant contact 600 comprises a coil-like structure configured with sufficient metal coating thickness to electrical current and a tip 112 at an end of the compliant contact 600 that is above the porous material 602. The compliant contact 600 can include an internal scaffold 116 (e.g., dielectric or polymer) that is coated with a conductive material 108. The porous material 602 can include a plurality of pores 604. Porosity can both reduce dielectric constant and modulus of elasticity for the matrix, and can be tailored for its function of supporting the compliant contact 600. In some cases, the porous material 602 can be a porous or rubbery substance, such as polymethyl methacrylate (PMMA), elastomers, etc., that provides mechanical stiffness. By fabricating compliant contacts 600 in a compliant dielectric substrate, lightweight long-span compliant contact sections can be supported and resist lateral load.

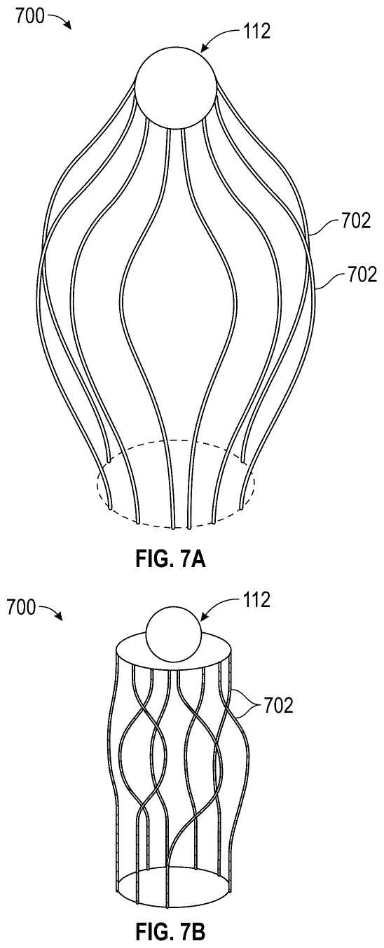

FIGS. 7A-7B illustrate compliant contacts 700 having radial and azimuthal flexures or elongate elements and a tip 112 centrally positioned relative to the flexures or struts 702, according to one embodiment. Thin, curved struts 702 can be fabricated with the 3D lithographic and metallization processes described with respect to at least FIGS. 1A-1E. As shown in FIGS. 7A and 7B, a suitable number (e.g., 3-20, such as 8 as shown) of these struts 702 to maintain vertical orientation and resist lateral loading can be fabricated such that they emanate from a rigid central post to the periphery. Each strut 702 can have a thickness in a range between about 3 μm and 10 μm, and each can have an arched morphology in a 3D space, which can enable uniform compliance in a vertical direction. FIG. 7A shows the struts 702 bending in a radial direction (e.g., the struts 702 bend or move radially out from a central axis of the compliant contact 700), while FIG. 7B shows the struts 702 bending tangentially, or at an angle of 90° to the radial direction (e.g., the struts 702 can bend in a way such that they follow the surface of a cylinder). In some cases, more than eight struts can be included. In some cases, fewer than eight struts can be included. With the illustrated configurations of FIGS. 7A-7B, the bending stiffness of the compliant contacts 700 can be decreased.

FIG. 8 illustrates a compliant contact 800 having ribbon supports 802 and a tip 112, according to one embodiment. The compliant contact 800 can be fabricated with the 3D lithographic and metallization processes described herein and with respect to at least FIGS. 1A-1E, and comprises the same types of materials. Three azimuthal ribbon supports 802 are illustrated in FIG. 8. In some cases, the number of bends 801 in the ribbon supports 802 can be repeated n-times (or until a desired height is achieved for the compliant contact 800, having desired compliance/strength characteristics or parameters). In some cases, the ribbon supports 802 are similar to sinusoids. In some cases, the lateral compliance of the tip 112 can be modified or adjusted by adjusting how the ribbon supports 802 are positioned relative to the compliant contact 800 as a whole. In the illustrated embodiment, the ribbon supports 802 are oriented to bend tangentially. In some cases, this can lend itself to maintaining vertical stability during compression in the process of testing a DUT.

FIG. 9 illustrates another compliant contact 900 having ribbon supports 802 and a tip 112. Unlike in FIG. 8, the ribbons supports 802 can surround an internal structure 902, according to one embodiment. The compliant contact 900 can be fabricated with the 3D lithographic and metallization processes described with respect to at least FIGS. 1A-1E, and comprises the same types of materials. Four azimuthal ribbons supports 802 are shown in FIG. 9 with an internal support structure 902 (e.g., internal bracing or structures that increase the overall rigidity of the compliant contact 900). The internal structure 902 can comprise a polymer scaffold or structure that is coated with a conductive material, such as a metallic material. The tip 112 can be a pad surface or a flat tip. In some cases, the internal structure 902 can facilitate flexible (linear) compression and further resist lateral loading in use. As in FIG. 8, the ribbon supports 802 are shown oriented tangentially relative to the overall circular pattern; in other cases, the ribbon supports can be oriented radially with respect to the internal structure 902. The illustrated arrangement can reduce risk of the internal structure 902, which connect to the ribbon supports 802, interfering with the vertical compression of the ribbon supports 802.

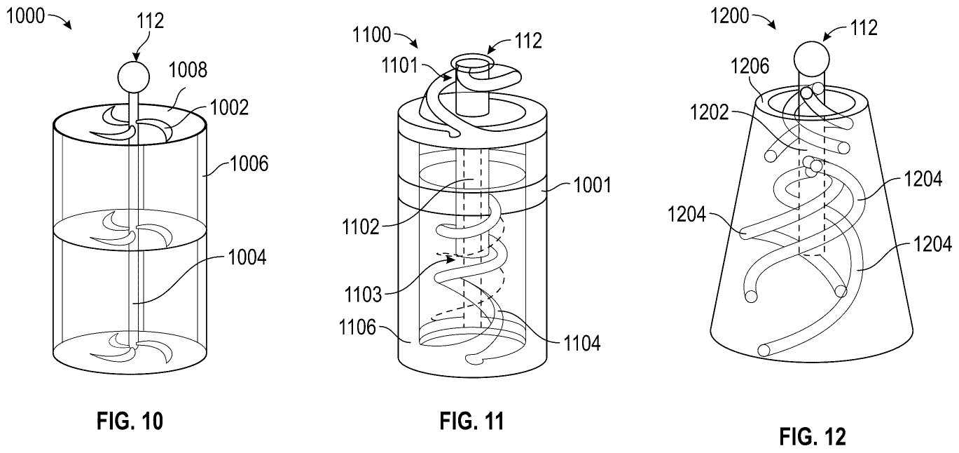

FIGS. 10-12 illustrate compliant contacts having a spring-like compliance and external supports. Unless otherwise noted, the fabrication processes, materials, and alternatives described herein and with respect to FIGS. 1A-1E are applicable to the compliant contact structures described in FIGS. 10-12. One or more helices with variable and non-uniform cross-sectional geometries, including overall diameter tapering and pitch variation, can be implemented with the compliant contacts. In some cases, multi-start designs (e.g., like springs in a parallel configuration) can increase stiffness. In some cases, the body of the compliant contacts 1000, 1100, 1200, can comprise one or more coils or other flexure mechanism 1004, 1104, 1204 that extend and compress in a direction parallel to a central axis of the body, and can also include external support structures 1006, 1106, 1206 that resist lateral loading during operation.

FIG. 10 shows a compliant contact 1000 having a plurality of disc flexures 1008 comprising a plurality of cutouts 1002 (e.g., half-moon cutouts or crescent cut-outs) extending from a central conductive and compressible pole 1004 at various levels or heights of the core 1004, a tip 112, and an external support 1006. In some cases, the external support 1006 can be non-electrically-conducting. In some cases, the external support 1006 can be metallized and capable of carrying an electrical current. In some cases, the core 1004 is solid, and in other cases, the core 1004 is a hollow cylinder. The core 1004 can comprise one or more relatively tight, conductively coated helical coils or multiple conductive fibers, configured to expand horizontally during vertical compression, such that the external support 1006 limits the horizontal expansion and thus limits the vertical compression.

FIG. 11 shows a compliant contact 1100 having a plunger or core 1102 with a tip 112, one or more coils 1104 (e.g., helical spring elements) surrounding and attached to a portion of the core 1102, and an external support structure 1106, according to one embodiment. As illustrated, the compliant contact 1100 can include a core 1102 or a plunger that is axially located with respect to the compliant contact 1100. Helical springs or coils 1104 can be formed at a first distal end 1101 of the core 1102 to provide an internal rotational mechanism, and the one or more coils 1104 can be formed at a second distal end 1103 of the core 1102. In some cases, multiple coils can be formed. In some cases, the coils 1104 proximate the tip 112 can extend from a cross ring-like structure at an angle that can yield a flat coil or a conical coil. In some cases, and as shown, an external support 1106 can be provided, increasing the overall rigidity of the compliant contact 1100. The metallized core 1102 can carry the current and include a structure that accommodates compression while maintaining conductivity between the tip 112 and the contact pad (see, e.g., FIGS. 5 and 20-21B and attendant description). Alternatively, the coils 1104 can carry current between tip 112 and the contact pad while the core 1102 can serve as an internal support to supplement the rigidity of the external support 1106.

FIG. 12 illustrates a compliant contact 1200 having a core 1202 or a plunger with a tip 112, and a plurality of coils 1204 or helical springs surrounding a portion of the core 1202. The coils 1204 can be arranged such that at least one of the coils 1204 is oriented in a clockwise direction and at least one of the coils 1204 is oriented in a counterclockwise direction, which can inhibit rotation of the tip 112 when the compliant contact 1200 is brought into contact with a surface of an electrically interfacing device and the compliant contact 1200 is compressed. An external support structure 1206 is additionally formed to surround and support the compliant contact 1200, which increases the effective rigidity and/or stability of the compliant contact 1200. In some cases, the coils 1204 comprise ends that are internally coupled to or attached to the external support structure 1206. In some cases, the cross-section of the filament shaped as a coil 1204 can be circular. In some cases, the cross-section of the filament shaped as a coil 1204 can be non-circular. In some cases, the external support structure 1206 can be tapered, such that an end of the external support structure 1206 that is proximate to the tip 112 has a smaller cross-sectional area than the opposing end of the external support structure 1206. In some cases, the external support structure 1206 can comprise a support sheath or comprise a plurality of elements that form a lattice-like structure. In some cases, the external support structure 1206 can be non-uniform and tapered and the compliant contact 1200 comprise counter-rotating helical spring elements. Having multiple layers of the coils 1204 can enable restrictions or constraints to lateral deflections, whether or not the device includes an external structure, which may be beneficial in electrically interfacing devices, such as DUTs, having larger pitches or wider pitch arrays.

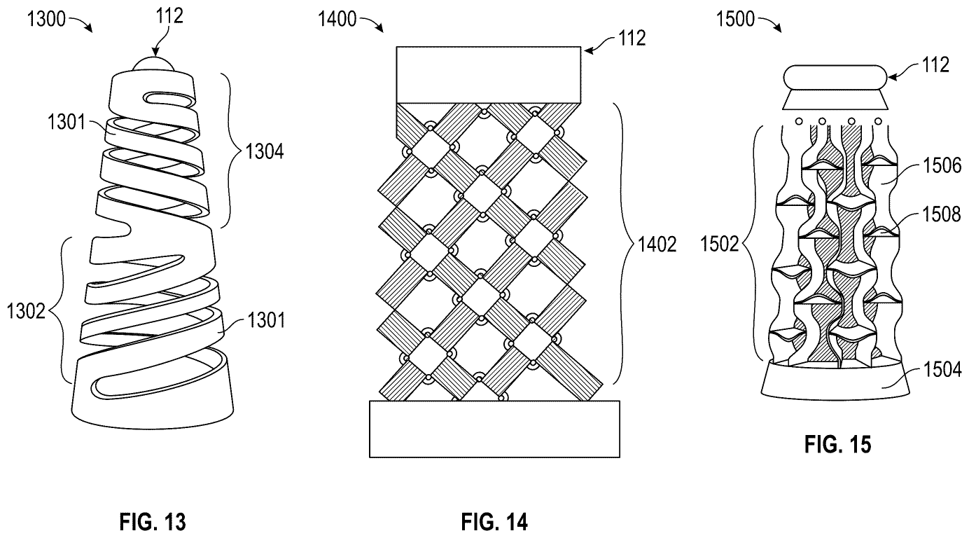

In some embodiments, a compliant contact 1300 or probe can have a counter rotating tapered spring geometry (e.g., a torsionally compliant spiral structure). Whereas FIG. 12 provides such a counter-rotation geometry by way of multiple coils of different orientations, FIG. 13 illustrates the compliant contact 1300 having a continuous coil structure with a first portion 1302 that spirals or rotates in one direction and a second portion 1304 that spirals or rotates in an opposite direction, according to one embodiment. The oppositely oriented spirals 1301 can inhibit rotation of the tip 112 when vertically compressing the compliant contact 1300. In some cases, a single spiral or multiple spiral start can be implemented. The fabrication processes and materials described herein and with respect to at least FIGS. 1A-1E apply to the compliant contact 1300 in FIG. 13. The compliant contact 1300 can be beneficial in cases where the tip 112 is brought into electrical contact with a surface that has a layer of oxide (e.g., copper oxide), which is insulating and can reduce the quality of the electrical contact. The compliant contact 1300, can be designed to break through or scratch the oxide to facilitate an improved electrical connection. Because the compliant contact 1300 is continuous between the multiple portions 1302, 1304, and includes oppositely oriented helices that promote stability, the coils 1302 themselves can carry current, obviating a separate core, internal supports and/or external supports. Of course, the skilled artisan will appreciate that the structure of FIG. 13 can also be combined with a core, internal or external support as taught elsewhere herein.

FIG. 14 illustrates a compliant contact 1400 having a lattice structure 1402, according to one embodiment. The fabrication processes and materials described herein and with respect to at least FIGS. 1A-1E apply to the compliant contact 1400 in FIG. 14. In some cases, the compliant contact 1400 configuration enables an entirely compressible element. The lattice structure 1402 of the compliant contact 1400 can itself carry current, obviating a separate core, and internal or external supports. The skilled artisan will appreciate that the structure of FIG. 14 can also be combined with a core, internal supports, or external supports, as taught elsewhere herein.

FIG. 15 illustrates a compliant contact 1500 having a lattice-like structure, according to one embodiment. The fabrication processes and materials described herein and with respect to at least FIGS. 1A-1E apply to the compliant contact 1500 in FIG. 15. In particular, FIG. 15 illustrates an example metamaterial compliant contact geometry. The particular example includes a combination of vertical flexure elements 1506 and horizontal linking elements 1508. In some cases, it may further include internal supports. More generally, the example illustrates the ability of 3D lithography and metallization processes to produce arbitrary geometries not limited by the 2D lithography processes used for traditional MEMS manufacture, resulting in distinct flexural designs, or exotic lattices for vertically compressible compliant contacts 1500. The compliant contact 1500 can comprise a bulk body structure with an engineered response under load. In some cases, the compliant contact 1500 can comprise an aperiodic structure, a lattice-based structure, a re-entrant hexagonal structure, an anisotropic structure, an isotropic structure, an auxetic or a non-auxetic structure, a variable symmetry structure, a multi-helical structure, a kagome lattice structure, a kirigami structure, an origami structure, an accordion structure, a sarrus linkage structure, a computationally-designed structure, a strut, a sheet, a block, a flexural structure, or a rigid structure. The metallized metamaterial structure 1502 of the compliant contact 1500 can have a peak strain between about 0.05 and 0.4. In some cases, the metallized metamaterial structure 1502 can have lattice spacing that is about less than or equal to 1 μm. In some cases, the base 1504 can have a diameter or a width between about 10 μm and 100 μm. In some embodiments, the compliancy of the compliant contact 1500 can be tuned to have a negative Poisson's ratio, such that as a force is exerted downwards onto the compliant contact 1500, the compliant contact 1500 can contract inwardly. This can allow for the fabrication of a microelectronic device with an increased number of compliant contacts that can be positioned closer together, which is beneficial for testing high bandwidth electronic components.

FIGS. 16A-16F are schematics showing a fabrication process for forming a microelectronic device 1600 having compliant contacts 1602. The fabrication processes and materials described with respect to at least FIGS. 1A-1E apply to the embodiments of FIGS. 16A-16F. In some embodiments, instead of forming a substantially monolithic primary structure or scaffold for each element or feature of the compliant contact, each element or feature of the compliant contact can be built from a plurality of template elements or template beams, which can form structures including lattices, fractals, stochastic solids, trusses, etc. The scaffolds are formed with a plurality of template elements 1601 that include a dielectric (or a polymer or other insulator) and then coated in a conductive material 108. Advantageously, the use of multiple template elements 1601 per compliant contact 1602 feature (e.g., coil filament, ribbon, core, strut, truss, etc.), facilitates quicker metallization due to a greater scaffold surface area being coated, and also facilitates tuning relative percentages of scaffold material vs. metal coating.

FIG. 16A shows the formation of three compliant contact scaffold structures 116 that are formed over corresponding contact pads 104, which are in or on a substrate 106. A magnified view of a portion 1604 of one in-process compliant contact 1602 is illustrated in FIG. 16B. FIG. 16B shows an example of the multi-element scaffold 116 that is formed with a plurality of template elements 1601. In the illustrated example, the scaffold 116 comprises a body-centered cubic lattice unit cell. In some cases, the scaffold 116 can include a repeating unit cell having a unit cell topology of at least one of a simple cubic, a body-centered cubic, a face-centered cubic, a kelvin cell, a diamond, a cubic-diamond, a tetrahedron, an octahedron, an octet-truss, an open cellular solid (e.g., triply periodic minimal surface (TPMS), plate (open cell), gyroid, etc.), etc. FIG. 16C shows early stages of conductive coating of the scaffold 116 with a conductive material 108.

A magnified view of a portion 1606 of the in-process compliant contact 1602 is illustrated in FIG. 16D. As indicated in this figure, the conductive material 108 is deposited over the surfaces of the template elements 1601, such that the conductive material 108 grows outward from each template element 1601 of the scaffold 116 and begins infilling the structure. FIG. 16E shows a completed microelectronic device 1600 after further deposition, showing three completed compliant contacts 1602. A magnified view of a portion 1608 of the compliant contact 1602 is shown in FIG. 16F. Beneficially, the implementation of a scaffold that is built from a plurality of template elements, can yield structures with higher conductive material amounts relative to the dielectric scaffold material, which enables better electrical conductivity.

Although FIGS. 16E-16F illustrate compliant contacts 1602 with approximately smooth exterior or outer surfaces, the surfaces may be non-smooth. In some cases, the exterior or outer surfaces can have a roughness that is an artifact of the fabrication process in which the metal is a result of merged deposition from multiple template elements 1601. For example, the surface roughness can be in the range of about 1 μm RMS to 10 μm RMS, whereas deposition on a single scaffold element per compliant contact feature may demonstrate significantly lower surface roughness of about 100 nm RMS to 800 nm RMS. In some cases, to mitigate the roughness, a scaffold having relatively small unit cells can be implemented. In some cases, the surface roughness of the compliant contacts 1602 is approximately proportional to the square of the distance between template elements 1601 and inversely proportional to the width of a template element 1601 with the deposited conductive material 108. In some embodiments, other artifacts can include periodic voids, or patterns of voids that correspond to growth patterns and/or removal of the scaffold material using the process of the FIGS. 16A-16F. In some cases, the coating on the template element can have the columnar grains normal to the surface they are grown on having specific orientations that are indicative of the intersection of different surface normals. Whether or not the scaffold remains in the final product, the columnar grains can be generally formed along an axis of elongation. The axis of elongation can be, for example, that of an individual polymer template element used to create the compliant contact 1602, whether or not the polymer is left in the final product. In other embodiments illustrated herein, wherein a single polymer template element is employed as the scaffold for each feature, such as the conductive core 202 or the helical spring 204 of FIG. 2A, the axis of elongation can be that of the elongated feature itself. Thus, the skilled artisan can determine from the pattern of grains in the compliant contact 1602 that it was formed by growth from template elements 1601 whether those template elements 1601 remain or were removed.

In some embodiments, the scaffold 116 remains embedded in the conductive material 108 in the compliant contact 1602, and can represent less than 50% of the volume of the compliant contact 1602, such as between about 0.001% and 25% of the volume, such that the metal of the compliant contact 1602 is sufficiently conductive. In some cases, the compliant contact 1602 can have between about a 50% and a 100% metal composition, such as between about 70% and 99.999% metal composition by volume or weight.

In some cases, a compliant contact 1602 having a core and a compliant element, such as a spring surrounding the core (e.g., FIG. 2A) or a plurality of compliant flexures (e.g., FIG. 2B), can independently be fabricated to have one or multiple scaffolding structures per feature prior to metallization. For example, the core and the compliant element can each include a substantially monolithic scaffold. In another example, the core can include a scaffold formed with a plurality of template elements, and the compliant element can include a substantially monolithic scaffold. In another example, the core and the compliant element can include a scaffold formed with a plurality of template elements.

As noted with respect to FIGS. 16A-16F, an individual feature (e.g., coil filament, ribbon, core, strut, truss, etc.) of a compliant contact can comprise a plurality of template elements 1601 to be coated with a conductive material 108. FIGS. 17A-17F illustrate other examples of such multi-element scaffolding for purposes of demonstrating the additional variables provided for tuning compliance, conductivity, rigidity, etc. by such a process. The fabrication processes and materials described with respect to at least FIGS. 1A-1E apply to the embodiments of FIGS. 17A-17F, which are schematics showing a compliant contact 1700 and various configurations for a cross-section 1702 of the compliant contact 1700, according to one embodiment. Although illustrated for the relatively simple compliant contact geometry of FIG. 1A, the skilled artisan will appreciate that the advantages of providing multi-element scaffolding per compliant contact feature are applicable to any of the compliant contact geometries shown or described herein.

As illustrated in FIG. 17A, a compliant contact 1700 can comprise a multi-element scaffold 116 that has been coated with a conductive material 108. The compliant contact 1700 can be formed over a contact pad 104 that is in or on a substrate 106. The compliant contact 1700 can also include a tip 112 formed at one end of the compliant contact 1700. For example, the tip 112 can be a crown-like tip as shown, or any other suitable configuration. The cross-section 1702 of a compliant contact 1700 can vary depending on the coatings that are deposited and on the dimensions or cross-sectional shapes of the plurality of template elements 1601. For example, FIG. 17B shows a cross-section 1702 having four template elements 1601 formed of a dielectric or insulating material. A conductive coating 108 has been formed over and grown outwards from each of the plurality of template elements 1601, and the growth from each template element 1601 merges to form the infilled cross-section. In some cases, and as shown in FIG. 17C, an additional material 1704 can be disposed directly over the plurality of template elements 1601, prior to the deposition of the conductive material 108. As shown, the additional material 1704 surrounds a single template element 1601 and does not contact the additional material 1704 surrounding other template elements 1601. In some cases, and as shown in FIG. 17D, the conductive material 108 can be deposited on the plurality of template elements 1601, where the conductive material 108 surrounding one template element 1601 does not touch or contact the conductive material 108 of the conductive material 108 surrounding another template element 1601. An additional material 1704 can then be deposited and encapsulate or surround the coated plurality of template elements 1601. In some cases, the conductive material 108 can be deposited on the plurality of template elements 1601 and grown outwardly to form a connected conductive structure. Then the additional material 1704 can be deposited over the conductive material 108. In some embodiments, the plurality of template elements 1601 may have varying cross-sections. For example, FIG. 17F shows two template elements 1601 having a first width, which is larger than a second width of two of the other template elements 1601. The non-uniformity can allow for different infilling rates of the conductive material 108, and deposition can continue after the state of FIG. 17F so that the conductive materials 108 merge. The additional material 1704 of each of FIGS. 17C-17E can also be conductive and contribute to overall conductivity of the compliant contact 1700, or can be insulating, and in either case can be selected to tune mechanical and electrical properties of the compliant contact.

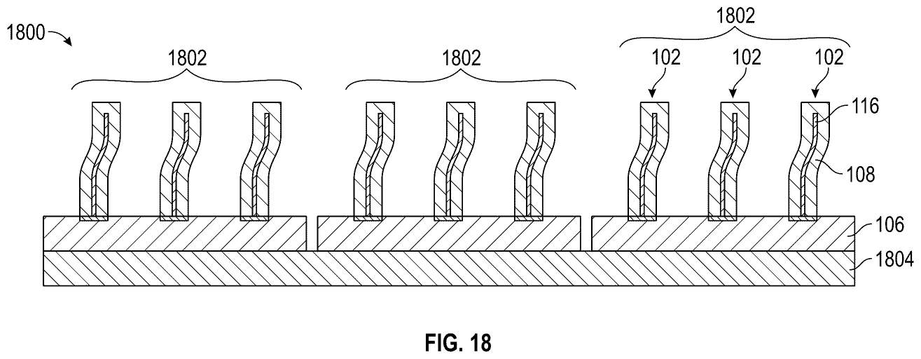

FIG. 18 is a side cross-section of a plurality of subsets 1802, each including multiple (e.g., rows or sub-arrays) compliant contacts 102, according to one embodiment. Unless otherwise noted, components of FIG. 18 are the same as or generally similar to like-numbered components of FIGS. 1A-17E, and alternatives noted above with respect to FIGS. 1A-17E are likewise applicable to FIG. 18. In some cases, a microelectronic device 1800 can be fabricated to include multiple subsets 1802 comprising arrays of compliant contacts 102. Each of the subsets 1802, including its own carrier substrate 106, can be manufactured and then coupled to a larger substrate 1804, which can be part of the final device (e.g., probe card). In that case, the carrier substrate 106 can include through substrate vias (TSVs) leading from their contact pads 104 to the backside of the carrier substrate 106 to aid in connection to the larger substrate 1804. Beneficially, such a process can reduce both manufacturing and transfer costs, relative to individual contact transfer manually or robotically, allowing multiple compliant contacts 102 to be transferred at a time. In some cases, the mechanical and electrical connection interface between the carrier substrates 106 and the larger substrate 1804 is structured to allow reversible connection, such that each subset 1802 can be removed and replaced with another sub-array upon the end of life for compliant contacts on the given subset 1802.

In some embodiments, FIG. 18 can represent a manufacturing arrangement, where the carrier substrates 106 represent sacrificial, handle, or transfer substrates, temporarily bonded to the larger substrate 1804 for manufacturing of the compliant contacts 102 as taught herein. In such an embodiment, each unit or “subset” 1802 for transfer can comprise a carrier substrate 106 and at least one compliant contact 102, such that each carrier substrate 106 can host a single compliant contact 102, a row of compliant contacts, or a sub-array of compliant contacts. By employing a larger substrate 1804 to host the individual carrier substrates 106 during manufacture, the processes described herein using 3D lithography and subsequent metallization can be used to manufacture many thousands of compliant contacts 102 at one time. After manufacture, the individual carrier substrates 106 can be detached from the manufacturing larger substrate 1804 using techniques known in the art for debonding or separating handle wafers during transfer of manufactured layers or structures. Alternatively, the carrier substrates 106 can be part of a larger substrate during manufacturing of the compliant contacts 102, and can be singulated from the larger substrate (e.g., by saw singulation) after manufacture of the compliant contacts 102.

The carrier substrates 106 can be configured to serve as handles, which may entail special structures for interacting with a robot end effector for transfer to another larger substrate (not shown) to form the microelectronic device 1800. After transfer to the larger substrate, unneeded portions or all of the carrier substrates 106 can be removed. For example, if the transfer is conducted by inverting the “subset” 1802 (which again can include a single or multiple compliant contacts 102 for this embodiment) over the final substrate (e.g., probe card), removal can be accomplished by removing the connection between the compliant contacts 102 and the carrier substrate 106 (lift-off processing), such as chemical lift-off (e.g., dissolving a temporary bonding material on which the compliant contacts were manufactured), laser lift-off, laser ablation, etc., or by obliterating the carrier substrate 106 using wet or dry etching techniques. If transfer is accomplished through inversion, then the manufactured compliant contacts 102 can be formed upside down with the tip 112 facing the carrier substrate 106. The tips 112 can be metallized after transfer, such as by sputtering with a shadow mask, or by dipping them in an electroplating solution. Alternatively, if the transfer is accomplished by mounting the carrier substrate 106 onto the larger probe card substrate, the entire carrier substrate 106 can be maintained in the final product, including conductive features for electrically connecting the compliant contacts 102 to pads of the probe card substrate, or undesired portions of the carrier substrate 106 can be selectively removed.

In some cases, the compliant contacts 102 or probes can be positioned or arranged in an array or a line, or can be a single compliant contact on the carrier substrate 106. In some cases, the carrier substrate 106 can have a through-substrate via (TSV) that extends through a thickness of the carrier substrate 106 (e.g., from the bottom to the top) to enable electrical and thermal connection between the compliant contact 102 and electrical routing on the lower substrate 1804 of the final electrically interfacing device. In some cases, the carrier substrate 106 includes routing between upper and lower contacts. The subsets 1802, including the carrier substrate 106 and the compliant contacts 102, can be attached with bonding techniques known in the art to a skilled artisan. In some cases, the attachment mechanism can include a permanent solder connection, a hybrid bond, or a semi-permanent or non-permanent mechanical connection or fixturing devices. Arrays of compliant contacts can be attached using a similar bonding process. In some cases, the compliant contacts or probes can be singulated from the substrate via liftoff techniques as described above, or can be subtractively machined away.

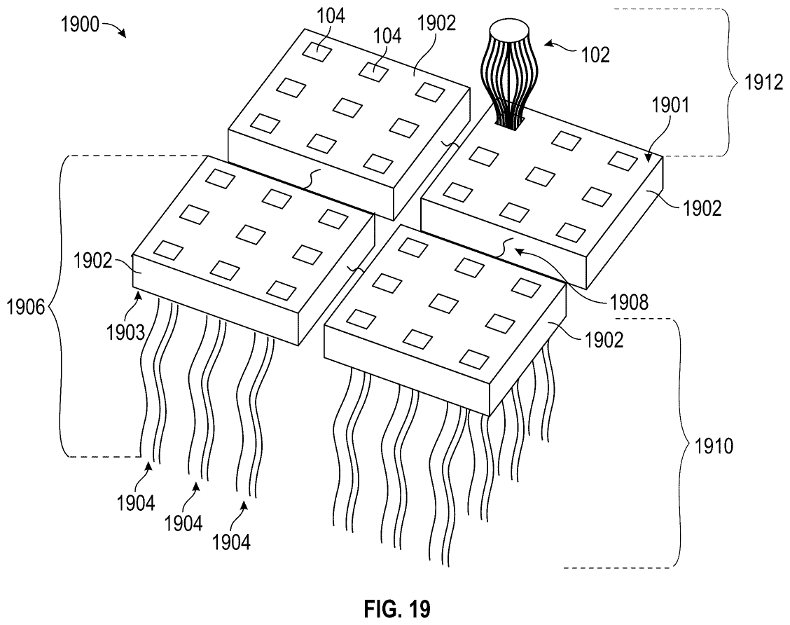

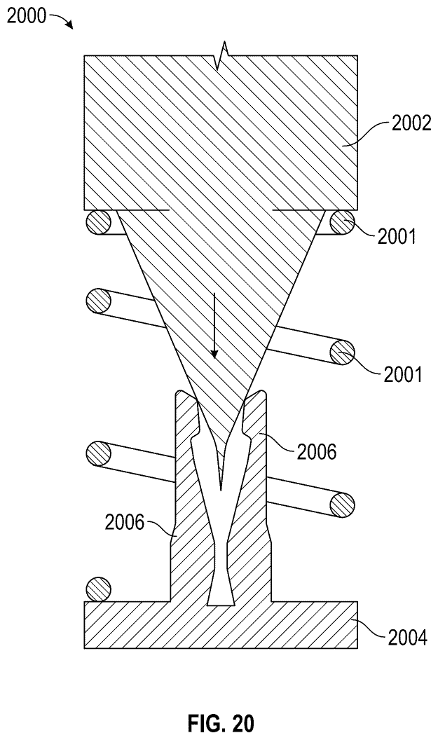

In some embodiments, the microelectronic device can include a hierarchically compliant configuration 1900. FIG. 19 is schematic view of an example hierarchical compliant configuration that includes a plurality of platforms 1902, where each platform 1902 can have a plurality of compliant contacts 102 on a first surface 1901 and a plurality of conductive supports 1904 on a second surface 1903 opposite the first surface, according to one embodiment. The platforms 1902 and their overlying compliant contacts 102 (one shown) can be formed, e.g., as described above for the subsets 1802 of FIG. 18. Unless otherwise noted, components of FIG. 19 are the same as or generally similar to like-numbered components of FIGS. 1A-18, and alternatives noted above with respect to FIGS. 1A-18 are likewise applicable to FIG. 19.

In some cases, the hierarchically compliant configuration 1900 can have a first layer 1910 that comprises coarse compliance structures 1904, which can mechanically and electrically connect to a larger substrate (not shown), and serve to compensate for wafer-level planarity variations. The hierarchically compliant configuration 1900 can additionally have a second layer 1912 that comprises compliant contacts 102, which can include fine 3D helical or flexure-based compliant contacts as described above, which can ensure consistent force contact (e.g., such as between about 0.5 gram force and 3 gram force) at each contact pad location of the electrically interfacing device. The plurality of conductive supports 1904 can have a first elastic modulus and the plurality of compliant contacts 102 can have a second elastic modulus, where the first elastic modulus is different from the second elastic modulus. In some cases, the hierarchically compliant configuration 1900 can comprise a plurality of units 1906 of these multi-layer structures (e.g., a unit 1906 would comprise the first layer 1910, the platform 1902, and the second layer 1912). In such cases, the units 1906 can also be laterally coupled to one another with any suitable mechanism 1908, and the coupling mechanism can also be compliant to permit some relative vertical motion in operation. In some embodiments, the plurality of platforms 1902 can be miniature PCB substrates, including polymer base material. In some cases, the plurality of conductive supports 1904 can have characteristics that allow for a certain level of flexibility to accommodate non-uniform surfaces of the electrically interfacing device. The platforms 1902 can include a plurality of through-substrate vias (TSVs) that extend through a thickness of the platform 1902. Such TSVs can electrically connect the compliant contacts 102 with the plurality of conductive supports 1904, which in turn connect with contact pads of the underlying (not shown). The hierarchically compliant configuration 1900 can be integrated into a microelectronic system, and can better accommodate non-planarity across the electrically interfacing device while still providing individual compliant contact OT that can remain in-specification despite a high degree of non-planarity in the electrically interfacing device. Further, the hierarchically compliant configuration 1900 can enable larger currents because the OT specification is typically shortened for the tightest pitch structures in the compliant contact array. In some cases, the first layer 1910 can have a larger cross-section and carry more current as compared to the second layer 1912. The flexures or the plurality of conductive supports 1904 of the first layer 1910 can also make contact with one another.

FIG. 20 is a side cross-section of a compliant contact 2000 having a two-part core comprising a male core portion 2002 and a female core portion 2004 having movable components 2006. The compliant contact 2000 includes a spring 2001 that engages with and permits relative vertical motion between the two core parts. The design of FIG. 20 is applicable, for example, to the compliant contact 200 of FIG. 2A. The fabrication processes and materials described herein and with respect to at least FIGS. 1A-1E apply to the compliant contact 2000 in FIG. 20. To ensure electrical and thermal conduction, the two core portions 2002, 2004 maintain physical contact of sufficient surface area throughout a range of the spring 2001 compression, representing the specified OT. Rotating, sliding, or flexural contacts can be made between the inner or outer body that allow for a sufficient area of contact throughout the OT range to allow for the desired current and thermal conduction capacity for various applications, such as for a test operation. The illustrated configuration shows one way in which good electrical contact can be achieved when assembling compliant contacts 2000 into a final structure or device. For example, the male portion 2002 of the core can have a conical shaped-end that facilely aligns to and couples with the female portion 2004 of the core. The movable components 2006 can be compliant and inwardly biased to maintain contact with the conical male portion 2002, and flex in an outward direction as the male portion 2002 and the female portion 2004 move toward one another under vertical compression during operation.

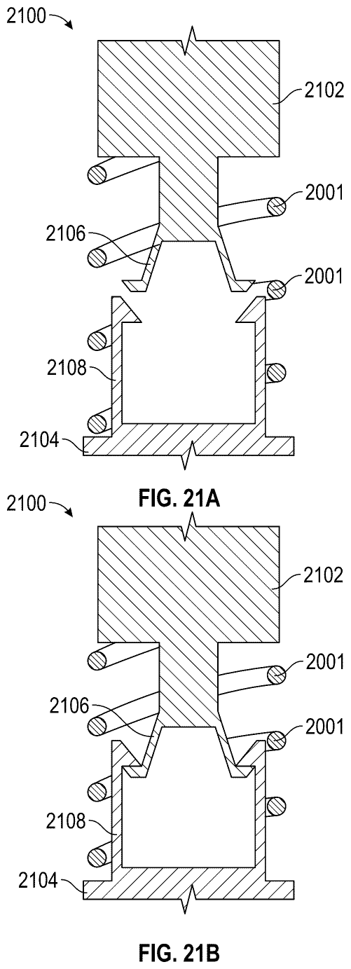

FIGS. 21A-21B are side cross-sections of a compliant contact 2100 having a two-part core 2102, including a male core portion 2102 and a female core portion 2104. The compliant contact 2100 includes a spring 2001 that engages with and permits relative vertical motion between the two core portions 2102, 2014. The fabrication processes and materials described herein and with respect to at least FIGS. 1A-1E apply to the compliant contact 2100 in FIGS. 21A-21B. Similar to FIG. 20, FIGS. 21A-21B illustrates an example compliant contact 2100 where the male core portion 2102 can join or mate with a female core portion 2104. In particular, the male core portion 2102 can comprise latching structures 2106, and the female core portion 2104 can comprise corresponding latching structures 2108. FIG. 21A shows the portions separated from one another. When compressed, ramped portions of the latching structures engage and deform the latching structures 2106 inwardly and/or the latching structures 2108 outwardly so that the tip of the latching structure 2106 slips past engagement detents or a ridge of the latching structures 2108. As shown in FIG. 21B, when the core 2102 and the core receptacle portion 2104 are coupled, the latching structures 2106 and the corresponding latching structures 2108 are mated and the contact is secured and the detents or ridges on both sides prevent disengagement. The latching structures 2106, 2108 are biased toward one another to permit constant engagement as they move vertically relative to one another and maintain electrical contact during compression while engaging with an electrically interfacing device. The two parts define an allowable OT during compression. In some cases, these may function as breakaway contacts or supports. Breakaway contacts or supports, such as those of FIGS. 20-21B, can be kept separate during the manufacturing process to allow for better precursor access during metallization of 3D lithography patterned scaffolds, and to prevent the metallization from fixing the parts to one another. The breakaway contacts can be designed to deflect and engage during assembly and during compression in use.

In some cases, the spring can be preloaded to tailor the force. In some cases, relief cuts can be made in the core portions to allow the spring 2001 and/or the core portions to deform without resulting in permanent deformation of the spring 2001 or the core portions. The assembly can be printed (e.g., 3D lithography) wholly as one body or several bodies during the same manufacturing process. With this process, independent picking and placing of the parts is not needed to form the contact. Robotic manipulation or other means of actuation can be used to perform various assemblies, such as pressing the springs 2001 so that one part of a two-part core can move past engagement detents. This function can be accomplished with the robotic or manual assembly tools used to place the contacts in the contact array of the final device, or they can occur using the substrate and all of the compliant contacts printed at once. While FIGS. 20-21B illustrate the spring as a helical coil, relative motion between core parts can be arranged with other spring configurations as disclosed herein.

A microelectronic device fabricated with a 3D lithographic process is described. Such fabrication processes include microstereolithography and multi-photon lithography (e.g., one-plus-one photon lithography, two-photon lithography), which utilize absorption properties such that photosensitive material becomes a chemically altered (e.g., cross-linked) polymer within the focal plane or focal spot of a rastering image or beam, relative to unexposed portions of the resist. Using a lithographic process, a compliant contact scaffold structure can be formed on or over a substrate comprising a plurality of contact pads. The compliant contact scaffold structure can correspond to a substantially monolithic structure or can comprise a plurality of uniform or non-uniform template elements. A deposition process can take place whereby a material such as a conductive material (or electrically conductive material) can be formed over the surfaces of the compliant contact scaffold structure until it has been infilled and a composite structure has been obtained. Further processing can also remove and/or replace the lithographically-formed scaffold (e.g., polymer), depending upon the desired final structure. Furthermore, the structure being formed can comprise one part after metallization (e.g., a spring of any type that also serves to carry current), or multiple parts (e.g., a spring and a multi-part core that serves to carry current). Different parts can be provided with different material properties with selective deposition processes.

Additional embodiments and system-level enhancements can be obtained. In some cases, an optional secondary printing and metallization can be implemented. If a hierarchical or multi-level structure is desired, the printing and metallization steps can be repeated. In some cases, guide plates, additional flexures, or bridging structures can be incorporated to tailor the mechanical response and lateral stiffness of the compliant contacts in the microelectronic device.

In some embodiments, a microfluidic chamber fill may be desired, as disclosed, for example, with respect to the embodiment of FIG. 5. For embodiments with hollow channels or internal cavities, liquid metal (e.g., Ga-In alloy) can be injected into said channels/cavities via microfluidic ports. In some cases, the chamber can be sealed or encapsulated. Internal recesses can also be incorporated to accommodate volume changes that may result during operation. In some cases, additional print steps or assembly steps can occur after forming the compliant contacts by 3D lithography and metallization (e.g., to install guide plates). In some cases, the hollow chambers or channels for liquid-metal reservoirs (e.g., Ga-In alloys) provide an ultra-low force, self-adjusting contact interface that maintains high conductivity without a conventional mechanical scraping force. Liquid metal can also be used as a deformable medium for low force contacting with a conducting tip section, which is immersed in the liquid. A vacuum can be drawn in the channels to increase adhesion between the tip of a compliant contact and the electrically interfacing device (e.g., DUT, etc.).

In some embodiments, funnel or conical alignment structures can be implemented. For example, a small funnel-shaped or conical guide feature can be 3D-printed as part of the tip or on a matching guide plate. When the contact pad (or a mating structure) of an electrically interfacing device approaches, the funnel geometry provides passive self-alignment (e.g., self-centering docking), which can reduce lateral force requirements and risk of pad damage. In some cases, enhanced over-travel tolerance is achieved. By guiding the pad into the correct position before high-force engagement, the structures minimize friction and reduce wear on both the tip and the electrically interfacing device.

In some embodiments, rotational docking platforms are implemented. A rotational docking mechanism, such as a small micro-gimbal, can be integrated at the base of a 3D spring. Under compression, the tip can freely tilt or rotate to optimize alignment with the contact pad. Additionally, lateral shear can be reduced. The rotational degree of freedom absorbs misalignment, preventing large shear forces and thereby lowering the total force for achieving stable contact. The same mechanism can also accommodate rotation caused by the flexure mechanism (e.g., helical spring(s)), rather than causing the tip to rotate and damage the contact pad of the electrically interfacing device (e.g., the contact pad of a DUT), and can obviate or be used in conjunction with the anti-rotation mechanisms, for example, of the embodiments of FIGS. 12-15.

In some embodiments, a compliant contact tip can comprise a drill tip or a micro-auger helix, similar to the embodiment of FIG. 4H. Such shapes can be designed to pierce or remove native oxide or contamination layers on contact pads of an electrically interfacing device via a drilling or cutting action that relies on torsional motion rather than pure downward force. The spring geometry can also be configured so that when compressed, the tip naturally rotates or scrubs the pad in a controlled manner that avoids excess damage to the pad, similar to a drill engaging material with minimal thrust.

In some embodiments, a multi-layered flexure platform can be fabricated, as described, for example, with respect to FIG. 18, allowing for hierarchical compliance and modular assembly. The multi-layered flexure platform can include printed multiple stacked compliance layers (e.g., a coarse compliance base for large misalignment plus a finer compliance layer near the tip). While FIG. 18 illustrates two levels of compliance, the skilled artisan will appreciate that greater numbers of levels can be provided. This mechanical “metamaterial” approach allows each layer to handle different displacement scales, ensuring consistent low force across the entire compliant contact array. Different layers can be metallized separately to create independent conductive paths, tailored compliance at different levels, or to segregate signals for improved noise performance.

In some embodiments, hybrid rigid-compliant zones are formed. A single compliant contact (e.g., probe) column can incorporate alternating rigid rings (like the rings 1001 of FIG. 11). FIGS. 10-12 generally illustrate contacts that can have hybrid rigid-compliant zones. FIG. 15 is also applicable, as the horizontal linking components 1508 of the metamaterial could be rigid versus the vertical flexure elements 1506, which could be compliant. Hybrid rigid-compliant zones provide lateral stability in certain regions and high compliance in others. By varying the density and placement of the rigid zones, one can fine-tune the force-deflection curve to match specific test requirements.

In some embodiments, energy-damping microstructures (e.g., FIGS. 6, 9-12, and 14-15) are formed, enabling shock absorption and vibration control. Internal lattice patterns or designed “crumple zones” in the 3D-printed scaffold can dissipate energy during sudden compressive or lateral shocks, safeguarding both the compliant contact and the electrically interfacing device. The structures also help dampen high-frequency vibrations, which can improve contact consistency in high-speed testing environments.

In some embodiments, embedded strain gauges are implemented. Real-time force sensing can occur when small conductive traces (e.g., meander-line resistors) are added or doping that provides a piezoresistive response is integrated. The sensor data allows for a feedback loop as it can be fed back into the test system to dynamically adjust overtravel or detect contact issues in real time.

In some embodiments, capacitively coupled force sensors for non-invasive sensing or localized sensing can be implemented. Instead of relying on resistive changes, a parallel plate or interdigitated capacitor can be incorporated into the design of the 3D spring structure. The capacitance changes upon compression or tilt, indicating the applied load. In some cases, the capacitive sensors can be localized at the tip region or base region of a compliant contact, enabling precise identification of where a deflection is occurring.

In some embodiments, thermal sensing through local temperature monitoring or joule heating diagnostics can be implemented. A thin-film resistance temperature detector (RTD) is embedded or a thermistor layer is provided near the tip. High-current tests can cause localized heating. Measuring real-time temperature helps avoid contact damage or signal drift. If the current-carrying path heats abnormally, it may indicate poor contact or a short-circuit condition, which can be quickly identified. For example, in some embodiments, the compliant contacts, such as any of the compliant contacts described herein and with respect to FIGS. 1A-21B, can have an effective coefficient of thermal expansion (CTE) that can be tuned to have a nonlinear and negative value. If an instance arises where excessive heating occurs as a result of an electrical short (significantly greater than the heat generated in normal operation), the CTE differential can be designed to cause the compliant contact to detach from the electrically interfacing device (such as a DUT), which can prevent complete failure.

In some embodiments, microfluidic cooling channels can be implemented, providing enhanced heat dissipation, and a modular fluid path. For high-current tests, tiny coolant channels can be integrated within or around the 3D compliant contact structure. A circulating fluid (e.g., water or a specialized coolant) dissipates heat, preserving stable electrical performance. The fluidic channels can be designed such that an individual compliant contact or probe (or a group of probes) has an independent cooling path, which minimizes crosstalk from thermal hotspots.

In some embodiments, pressurized fluid-assisted contact can be implemented to facilitate cleaning the interface and providing a fluid-actuated seal. A gentle flow of inert or conductive fluid can be introduced near the compliant contact tip to flush away debris or oxide, which improves contact reliability without high mechanical force. A pressurized fluid layer can also create a mild vacuum or positive pressure that helps hold the contact pad of the electrically interfacing device against the tip of the compliant contact for consistent contact.

In some embodiments, vacuum-assisted alignment can be implemented through a negative pressure lock and with low-force contact. Channels can be incorporated at the compliant contact tip or around it and apply localized vacuum, which gently pulls the contact pad of the electrically interfacing device into correct alignment. The approach allows the compliant contact or probe to maintain intimate contact with the pad using negative pressure rather than a large compressive load, thereby reducing pad damage risk.

In some embodiments, 3D routing for crosstalk mitigation can be implemented via spatial separation and optimized ground/shield placement. The compliant contacts can be printed in 3D space such that sensitive signal lines follow routes that avoid one another, reducing electromagnetic coupling. 3D metallic walls or partial enclosures that act as shields or return paths can also be implemented. In some cases, the 3D metallic walls or partial enclosures surround individual compliant contacts, such as in FIGS. 10-12 (e.g., the external support 1106, 1106, 1206 of FIGS. 10-12 could be electrically isolated from the tip 112). In some cases, the 3D metallic walls or partial enclosures surround groups or sub-arrays or subsets of compliant contacts. The 3D metallic walls or partial enclosures can enhance signal integrity in high-frequency testing.

In some embodiments, integrated filtering or embedded passive components can be implemented with on-probe or on-compliant contact LC filters and miniaturized resonators. The ability to filter a signal at each individual contact can allow for additional tunability as compared to systems where the filtering occurs in the integrated circuit or the automated test equipment to which the contacts are attached, especially given that such systems have a limited number of channels and footprint. Small inductors (helical coils) and capacitors (parallel plates) can be built directly into the 3D structure, which creates distributed filtering or impedance matching, especially for RF testing. Resonant elements can be integrated to test specific frequencies or to provide built-in noise filtering. In some cases, embedding passive components can mitigate or smooth high current spikes, which could help prevent damage to a probe card or test socket if there is a short within the electrically interfacing device.

In some embodiments, coaxial or triaxial compliant contacts can be fabricated with multiple concentric conductors and single-structure construction. A central conductor, an insulating shell, and one or more outer conductor layers (for shield or guard) can be fabricated. This yields coax or triax lines for high-frequency or low-noise measurements. Unlike conventional processes requiring multiple separate parts, multiphoton lithography can print the entire multi-layer arrangement in one step, then selectively metallize each layer. Such coaxial/triaxial conductor structures can be provided, for example, in the structure of the conductive cores of embodiments in which the cores are the primary current carrier, or into the flexure structures or springs of embodiments in which they are the primary current carrier.

In some embodiments, differential pair spring structures can be implemented as paired lines, which can reduce electromagnetic interference. Two parallel, closely spaced spring arms with matched geometry, such as those of FIGS. 3A and 3B, can be printed such that each pair acts as a differential signal line, maintaining consistent impedance. Keeping the lines in tight 3D proximity prevents external noise injection and limits crosstalk between adjacent pairs.

In some embodiments, a collapsible “skirt” or sheath or bellows can be implemented, forming a protective envelope and enabling controlled collapse. Each compliant contact or probe can be surrounded by a thin, collapsible wall that only deforms after the tip has made contact. This can protect the spring from unintentional lateral impacts. The skirt can also be designed to buckle in a predictable manner, absorbing extra force if the compliant contact is over-compressed.

In some embodiments, shock-absorbing “fenders” can be implemented as outer bumper structures and with a modular installation. Robust outer frames or “fenders” can be printed around groups of compliant contacts. These fenders absorb large lateral shocks before they reach the more delicate 3D springs, which prolongs the compliant contact life. The fenders or bumpers can be implemented in sections, allowing specific zones of the array to have additional protection where needed.

In some embodiments, environmental sealing can be implemented, in which a compliant contact with a compliant core is encapsulated, enabling corrosion-resistant operation. A polymer or a thin, less corrodible metallic shell can be printed around the entire spring mechanism, leaving an aperture at the tip of the compliant contact to isolate the spring from moisture or contaminants but still permit conductive contact with the contact pad of an electrically interfacing device. Such sealing can be crucial in harsh testing environments (e.g., high humidity or chemical exposure).

With 3D lithography (e.g., multi-photon, single photon, microstereolithography, etc.) and post-metallization (e.g., direct photo-reductive lithographic metal printing, etc.) processes, a 3D microfabricated, ultra-low force, high-current contact structure can be produced. These compliant contacts can be directly written on top of contact pads of the target substrate (e.g., standard PCBs, silicon interposers, ceramic carriers, etc.), which simplifies assembly and reduces the reliance on external bonding processes. Because of the 3D spring/flexure geometries (e.g., helices, latticed-based flexures, multi-ribbon arrays), individual compliant contacts will utilize less force as compared to conventional probes (e.g., at least approximately ten times less force) to establish good electrical contact. The compliant contacts can support high current. Selective metallization (e.g., ALD, sputtering, electroless, electroplating, etc.) on the polymer scaffolds can yield robust conductive surfaces. Thick metallic layers or specialized alloys can be used to handle high currents with minimal Joule heating and stable contact resistance. Generally, the compliant contacts disclosed herein exhibit compliance, lateral load resistance, and improved contact reliability over traditional 2D MEMS probes. Additionally, they allow for high compliant contact density. Because the force per compliant contact is low, many more compliant contacts can fit into a standard total load budget, which increases parallel testing capabilities and the ability to control contact pad damage in the electrically interfacing device. The 3D fabrication also allows many electrical paths to connect the tip to its contact pad (e.g., by way of multiple ribbons or helical springs), and the compliant contacts can be engineered to function with multiple missing or failed elements.

Regarding alignment, the compliant contacts and the microelectronic device can facilitate misalignment compensation. Multiple sets of flexures that can be arranged (e.g., radially, azimuthally, rectilinearly, etc.) can provide controllable built-in compliance in the vertical Z-direction and in the XY-plane. Additionally, printing multiple hierarchical layers or platforms allows correction for significant topography variations or tilt under even lesser loads.

The microelectronic device or electrically interfacing device and compliant contacts described herein possess mechanical and electrical advantages. Compliant contacts having helical or multi-beam structures can be engineered to have nearly linear or nonlinear (progressive or degressive) spring constants, giving designers/manufacturers flexible control over contact mechanics. The thick electroplated metals (e.g., Cu, Ni alloys, etc.) with an optional noble metal cap (e.g., Au) allows for both high conductivity and corrosion resistance (e.g., high current capacity). 3D flexures can accommodate out-of-plane tilt without significantly increasing contact force, and guide plates, outer support frames, or the overall geometry can be integrated to resist lateral shear loads, allowing for misalignment tolerance and lateral robustness. Additionally, tailored contact scrubs can be achieved. By offsetting the compliant feature (e.g., spring) centerline or using asymmetrical flexures, the tip can produce a beneficial “wiping” action to remove oxides, which lowers contact resistance.

In some aspects, the techniques described herein relate to a compliant contact including: a body including and extending between a first end and a second end, wherein the second end is configured to couple to an electrically interfacing device; and a conductive material, wherein the conductive material defines an outer surface of the body, wherein the body is formed with a 3D lithographic process and a metallization process.

In some embodiments, the techniques described herein relate to a compliant contact, wherein the conductive material includes columnar grains that have an orientation that is about normal to an axis of elongation. In some embodiments, the techniques described herein relate to a compliant contact, wherein the compliant contact includes one or more voids that are artifacts of the 3D lithographic and metallization processes.

In some embodiments, the techniques described herein relate to a compliant contact, wherein the body includes a tip at the second end, and wherein the first end is to couple to a contact pad. In some embodiments, the techniques described herein relate to a compliant contact, wherein the tip includes a shape, wherein the shape includes a sphere, a hyperboloid, a pyramid, a wedge, a crown, a multi-wedge, a screw tip, or multiple contact protrusions.

In some embodiments, the techniques described herein relate to a compliant contact, wherein the body includes a core and a plurality of compliant elongate elements surrounding the core. In some embodiments, the techniques described herein relate to a compliant contact, wherein the body includes a support and a plurality of compliant elongate elements surrounding the support. In some embodiments, the techniques described herein relate to a compliant contact, wherein the body includes a core and a spring surrounding the core. In some embodiments, the techniques described herein relate to a compliant contact, wherein the body includes a compliant core. In some embodiments, the techniques described herein relate to a compliant contact, wherein the body includes a scaffold and the conductive material disposed over the scaffold. In some embodiments, the techniques described herein relate to a compliant contact, wherein the scaffold includes a plurality of template elements. In some embodiments, the techniques described herein relate to a compliant contact, wherein the scaffold includes a dielectric. In some embodiments, the techniques described herein relate to a compliant contact, wherein the scaffold includes a polymer. In some embodiments, the techniques described herein relate to a compliant contact, wherein the body includes a plurality of components including a first component and a second component, wherein the first component has a first elastic modulus, and wherein the second component has a second elastic modulus different than the first elastic modulus.

In some embodiments, the techniques described herein relate to a compliant contact, wherein the body includes a structure for offgassing.

In some embodiments, the techniques described herein relate to a compliant contact, wherein the body includes a morphology corresponding to an artificial intelligence generated design.

In some embodiments, the techniques described herein relate to a compliant contact, wherein the body includes a plunger and a cavity. In some embodiments, the techniques described herein relate to a compliant contact, wherein the cavity is filled with a conductive fluid. In some embodiments, the techniques described herein relate to a compliant contact, further including one or more springs or flexures surrounding a first portion of the plunger, wherein a second portion of the plunger is configured to make contact with the conductive fluid.

In some embodiments, the techniques described herein relate to a compliant contact, wherein the body includes a coil and a tip, wherein the coil extends from at least the first end of the compliant contact. In some embodiments, the techniques described herein relate to a compliant contact, wherein the body includes a coil or a ribbon morphology, wherein the coil or the ribbon morphology extends from at least the first end of the compliant contact. In some embodiments, the techniques described herein relate to a compliant contact, further including a porous material, wherein the coil is embedded in the porous material and the tip is above the porous material.

In some embodiments, the techniques described herein relate to a compliant contact, wherein the body includes a plurality of compliant elements about a central axis and a tip along the central axis, wherein the plurality of compliant elements includes elongated radial and azimuthal flexures. In some embodiments, the techniques described herein relate to a compliant contact, wherein the body includes one or more compliant elements about a central axis and a tip along the central axis.

In some embodiments, the techniques described herein relate to a compliant contact, wherein the body includes a ribbon morphology. In some embodiments, the techniques described herein relate to a compliant contact, wherein the ribbon morphology surrounds an internal support structure.

In some embodiments, the techniques described herein relate to a compliant contact, wherein the body includes an external support structure surrounding a core, wherein the core is electrically conductive. In some embodiments, the techniques described herein relate to a compliant contact, wherein the body includes one or more coils extending in a direction parallel to a central axis of the body. In some embodiments, the techniques described herein relate to a compliant contact, wherein the one or more coils includes a first coil and a second coil, wherein the first coil rotates in a first direction, wherein the second coil rotates in a second direction opposite the first direction.

In some embodiments, the techniques described herein relate to a compliant contact, wherein the body includes a counter-rotation structure.

In some embodiments, the techniques described herein relate to a compliant contact, wherein the body includes a lattice structure. In some embodiments, the techniques described herein relate to a compliant contact, wherein the body includes a lattice-like structure.

In some embodiments, the techniques described herein relate to a compliant contact, wherein the body includes a spring surrounding a core, wherein the core includes a male portion and a female portion, wherein the male portion is configured to couple with the female portion. In some embodiments, the techniques described herein relate to a compliant contact, further including a detent, wherein the detent maintains a coupling between the male portion and the female portion.

In some embodiments, the techniques described herein relate to a compliant contact, wherein the body includes a scaffold formed with the 3D lithographic process, wherein the scaffold includes a first material having a first shape; and a first member including the conductive material surrounding the scaffold, wherein the outer surface includes a second shape defined by a deposition of the conductive material over the scaffold.

In some embodiments, the techniques described herein relate to a compliant contact, wherein the body includes a void surrounded by the conductive material.

In some embodiments, the techniques described herein relate to a compliant contact, wherein the body includes a resistivity value in a range between about 1.6 μΩ·cm and 50 μΩ·cm.

In some aspects, the techniques described herein relate to a method of forming a compliant contact, the method including: forming a scaffold with a 3D lithographic process; and forming a conductive layer over the scaffold, wherein the conductive layer defines an outer surface of the scaffold.

In some embodiments, the techniques described herein relate to a method, further including forming a tip, wherein the tip includes a shape, wherein the shape includes a sphere, a hyperboloid, a pyramid, a wedge, a crown, a multi-wedge, a screw tip, or multiple contact protrusions. In some embodiments, the techniques described herein relate to a method, wherein the scaffold includes a dielectric material. In some embodiments, the techniques described herein relate to a method, further including removing the dielectric material. In some embodiments, the techniques described herein relate to a method, further including removing the scaffold. In some embodiments, the techniques described herein relate to a method, wherein the conductive layer includes columnar grains that are normal to a surface of the scaffold on which it is formed. In some embodiments, the techniques described herein relate to a method, wherein the scaffold includes a polymer.

In some embodiments, the techniques described herein relate to a method, further including replacing the dielectric material with another material.

In some embodiments, the techniques described herein relate to a method, wherein the scaffold includes a plurality of template elements. In some embodiments, the techniques described herein relate to a method, wherein the scaffold includes a first portion for forming a core, wherein the scaffold includes a second portion for forming one or more beams or coils to surround the core.

In some embodiments, the techniques described herein relate to a method, wherein the compliant contact includes a first elastic modulus corresponding to the core and a second elastic modulus corresponding to the one or more beams or coils.

In some embodiments, the techniques described herein relate to a method, wherein the scaffold forms a shape corresponding to a spring.

In some embodiments, the techniques described herein relate to a method, further including forming one or more voids to remove the dielectric material.

In some aspects, the techniques described herein relate to a microelectronic device including: a substrate including a plurality of contact pads; and a plurality of compliant contacts disposed over and electrically connected to the plurality of contact pads, wherein the plurality of compliant contacts includes a first compliant contact formed with a 3D lithographic process and a metallization process.

In some embodiments, the techniques described herein relate to a microelectronic device, wherein the first compliant contact includes a tip and a core, wherein the tip is disposed at a first end of the first compliant contact, and wherein a second end of the first compliant contact contacts a first contact pad of the plurality of contact pads. In some embodiments, the techniques described herein relate to a microelectronic device, wherein the first compliant contact comprises a tip, wherein the tip is disposed at a first end of the first compliant contact, and wherein a second end of the first compliant contact contacts a first contact pad of the plurality of contact pads. In some embodiments, the techniques described herein relate to a microelectronic device, wherein the first compliant contact includes a plurality of compliant elongate elements surrounding the core. In some embodiments, the techniques described herein relate to a microelectronic device, wherein the tip includes a shape, wherein the shape includes a sphere, a hyperboloid, a pyramid, a wedge, a crown, a multi-wedge, a screw tip, or multiple contact protrusions.

In some embodiments, the techniques described herein relate to a microelectronic device, wherein the first compliant contact includes a support and a plurality of compliant elongate elements surrounding the support. In some embodiments, the techniques described herein relate to a microelectronic device, wherein the first compliant contact includes a core and a spring surrounding the core. In some embodiments, the techniques described herein relate to a microelectronic device, wherein the first compliant contact includes a scaffold and a conductive material disposed over the scaffold.

In some embodiments, the techniques described herein relate to a microelectronic device, wherein the scaffold includes a plurality of template elements. In some embodiments, the techniques described herein relate to a microelectronic device, wherein the scaffold includes a dielectric.

In some embodiments, the techniques described herein relate to a microelectronic device, wherein the first compliant contact includes a structure for offgassing.

In some embodiments, the techniques described herein relate to a microelectronic device, wherein the plurality of compliant contacts includes nested compliant contacts.

In some embodiments, the techniques described herein relate to a microelectronic device, wherein the plurality of compliant contacts includes an artificial intelligence generated design.

In some embodiments, the techniques described herein relate to a microelectronic device, wherein the plurality of compliant contacts includes a plurality of nested springs.

In some embodiments, the techniques described herein relate to a microelectronic device, wherein the first compliant contact includes a plunger and a cavity. In some embodiments, the techniques described herein relate to a microelectronic device, wherein the cavity is filled with a conductive fluid. In some embodiments, the techniques described herein relate to a microelectronic device, further including one or more springs or flexures surrounding a first end of the first compliant contact opposite a second end of the first compliant contact, the second end to contact the conductive fluid.

In some embodiments, the techniques described herein relate to a microelectronic device, wherein the first compliant contact includes a coil and a tip, wherein the coil extends from a first contact pad of the plurality of contact pads. In some embodiments, the techniques described herein relate to a microelectronic device, further including a porous material, wherein the coil is embedded in the porous material and the tip is above the porous material.

In some embodiments, the techniques described herein relate to a microelectronic device, wherein the first compliant contact includes a plurality of compliant elements about a central axis and a tip along the central axis, wherein the plurality of compliant elements includes elongated radial and azimuthal flexures.

In some embodiments, the techniques described herein relate to a microelectronic device, wherein the first compliant contact includes a ribbon morphology. In some embodiments, the techniques described herein relate to a microelectronic device, wherein the ribbon morphology surrounds an internal support structure.

In some embodiments, the techniques described herein relate to a microelectronic device, wherein the first compliant contact includes an external support structure surrounding a core, wherein the core is electrically conductive. In some embodiments, the techniques described herein relate to a microelectronic device, further including one or more coils surrounding a portion of the core.

In some embodiments, the techniques described herein relate to a microelectronic device, wherein the one or more coils includes a first coil and a second coil, wherein the first coil rotates in a first direction, wherein the second coil rotates in a second direction opposite the first direction.

In some embodiments, the techniques described herein relate to a microelectronic device, wherein the first compliant contact includes a counter-rotation structure. In some embodiments, the techniques described herein relate to a microelectronic device, wherein the first compliant contact includes a lattice structure. In some embodiments, the techniques described herein relate to a microelectronic device, wherein the first compliant contact includes a lattice-like structure.

In some embodiments, the techniques described herein relate to a microelectronic device, further including a plurality of sub-arrays of compliant contacts, including a first sub-array of compliant contacts and a second sub-array of compliant contacts, wherein the first sub-array of compliant contacts includes the plurality of compliant contacts, and wherein the second sub-array of compliant contacts includes a second plurality of compliant contacts. In some embodiments, the techniques described herein relate to a microelectronic device, wherein an individual sub-array of compliant contacts of the plurality of sub-arrays of compliant contacts is removable.

In some embodiments, the techniques described herein relate to a microelectronic device, further including a multi-level hierarchical configuration. In some embodiments, the techniques described herein relate to a microelectronic device, wherein the multi-level hierarchical configuration includes a first layer of conductive supports, a second layer of platforms, and a third layer of compliant contacts, wherein the first layer of conductive supports are electrically connected to the plurality of contact pads, wherein the conductive supports are disposed below the second layer of platforms, wherein the third layer of compliant contacts are disposed above the second layer of platforms, and wherein the third layer of compliant contacts includes the plurality of compliant contacts.

In some embodiments, the techniques described herein relate to a microelectronic device, wherein the first compliant contact includes a spring surrounding a core, wherein the core includes a male portion and a female portion, wherein the male portion is configured to couple with the female portion. In some embodiments, the techniques described herein relate to a microelectronic device, further including a detent, wherein the detent maintains a coupling between the male portion and the female portion.

In some embodiments, the techniques described herein relate to a microelectronic device, wherein the first compliant contact includes: a scaffold formed with the 3D lithographic process, wherein the scaffold includes a first material having a first shape; and a first member including a conductive material surrounding the scaffold, wherein the conductive material defines an outer surface of the first member, and wherein the outer surface includes a second shape defined by a deposition of the conductive material over the scaffold. In some embodiments, the techniques described herein relate to a microelectronic device, wherein the conductive material makes up between approximately 50% and 100% of a composition of the first compliant contact.

In some embodiments, the techniques described herein relate to a microelectronic device, further including one or more voids, wherein the one or more voids are artifacts of the 3D lithographic process. In some embodiments, the techniques described herein relate to a microelectronic device, wherein the first compliant contact includes a coil structure to reduce a compressive force to establish electrical contact between the first compliant contact and a device under test. In some embodiments, the techniques described herein relate to a microelectronic device, wherein the first compliant contact includes a dielectric interior surrounded by a conductive material. In some embodiments, the techniques described herein relate to a microelectronic device, wherein the first compliant contact includes an elastic modulus value in a range between about 100 MPa and 200 GPa. In some embodiments, the techniques described herein relate to a microelectronic device, wherein the first compliant contact includes a resistivity value in a range between about 1.6 μΩ·cm and 50 μΩ·cm.

In some aspects, the techniques described herein relate to a method of forming a microelectronic device, the method including: forming a plurality of compliant contacts including a first compliant contact, with a 3D lithographic process and a deposition process, wherein the deposition process forms a conductive layer that defines an outer surface of the first compliant contact; and electrically connecting the first compliant contact with a first contact pad.

In some embodiments, the techniques described herein relate to a method, wherein the deposition process electrically connects the first compliant contact with the first contact pad.

In some embodiments, the techniques described herein relate to a method, further including forming a tip at an end of the first compliant contact to electrically connect to an electrically interfacing device, wherein the tip includes a shape, wherein the shape includes a sphere, a hyperboloid, a pyramid, a wedge, a crown, a multi-wedge, a screw tip, or multiple contact protrusions.

In some embodiments, the techniques described herein relate to a method, wherein the first compliant contact includes a scaffold having a dielectric material, wherein the conductive layer is disposed over the scaffold. In some embodiments, the techniques described herein relate to a method, further including removing the dielectric material. In some embodiments, the techniques described herein relate to a method, further including replacing the dielectric material with another material. In some embodiments, the techniques described herein relate to a method, wherein the scaffold includes a plurality of template elements. In some embodiments, the techniques described herein relate to a method, wherein the scaffold includes a first portion for forming a core, wherein the scaffold includes a second portion for forming one or more compliant elements to surround the core. In some embodiments, the techniques described herein relate to a method, wherein the scaffold forms a shape corresponding to a spring.

In some embodiments, the techniques described herein relate to a method, further including providing a substrate including a plurality of contact pads, wherein the plurality of contact pads includes the first contact pad.

In some aspects, the techniques described herein relate to a compliant contact including: a scaffold comprising a polymer; a conductive material surrounding the scaffold; and an outer surface, wherein the conductive material defines the outer surface.

In some embodiments, the techniques described herein relate to a compliant contact, wherein the polymer is a polymerized resin. In some embodiments, the techniques described herein relate to a compliant contact, wherein the polymer is a cross-linked polymer. In some embodiments, the techniques described herein relate to a compliant contact, wherein the conductive material includes at least one of a copper, nickel, or a nickel alloy.

In some embodiments, the techniques described herein relate to a compliant contact, wherein the outer surface includes a morphology corresponding to a compliant structure. In some embodiments, the techniques described herein relate to a compliant contact, wherein the outer surface includes a morphology corresponding to a core surrounded by a spring. In some embodiments, the techniques described herein relate to a compliant contact, wherein the outer surface includes a morphology corresponding to a coil. In some embodiments, the techniques described herein relate to a compliant contact, wherein the outer surface includes a morphology corresponding to a support structure surrounded by one or more elongate and flexible structures.

In some aspects, the techniques described herein relate to a microelectronic device including: a first compliant contact to electrically connect with an electrically interfacing device, wherein the first compliant contact includes a first inner shape comprising a polymer, wherein the first compliant contact includes a conductive material that defines a first outer shape, and wherein the first outer shape is formed with a deposition process.

In some embodiments, the techniques described herein relate to a microelectronic device, further including a carrier or a substrate, wherein the carrier or the substrate includes a first contact pad, wherein the first compliant contact is electrically connected to the first contact pad.

In some embodiments, the techniques described herein relate to a microelectronic device, further including an array of compliant contacts including the first compliant contact and a substrate including a plurality of contact pads including a first contact pad, wherein the array of compliant contacts is electrically connected with the plurality of contact pads. In some embodiments, the techniques described herein relate to a microelectronic device, wherein the array of compliant contacts includes a first sub-array of compliant contacts, wherein the first sub-array of compliant contacts are removable with respect to the substrate.

In some embodiments, the techniques described herein relate to a microelectronic device, wherein the first compliant contact includes an elastic modulus in a range between about 100 MPa and 200 GPa.

In some aspects, the techniques described herein relate to a method of forming a microelectronic device, the method including: forming a compliant contact, the compliant contact to electrically connect with an electrically interfacing device, wherein forming the compliant contact includes: forming a first inner shape with 3D lithography; and depositing a conductive material over the first inner shape, wherein the conductive material defines a first outer shape.

In some embodiments, the techniques described herein relate to a method, wherein the compliant contact is formed over a substrate including a plurality of contact pads.

In some embodiments, the techniques described herein relate to a method, further including providing a substrate including a first contact pad, and positioning and coupling the compliant contact to the first contact pad.

In some aspects, the techniques described herein relate to a microelectronic device including: a plurality of platforms, including a first platform and a second platform, wherein the first platform includes a first upper surface, wherein the second platform includes a second upper surface; a first plurality of conductive supports disposed on a first lower surface of the first platform, wherein the first lower surface is opposite the first upper surface; a first plurality of compliant contacts disposed over the first upper surface; a second plurality of conductive supports disposed on a second lower surface of the second platform, wherein the second lower surface is opposite the second upper surface; and a second plurality of compliant contacts disposed over the second upper surface, wherein the first plurality of conductive supports is in electrical connection with the first plurality of compliant contacts, and wherein the second plurality of conductive supports is in electrical connection with the second plurality of compliant contacts.

In some embodiments, the techniques described herein relate to a microelectronic device, wherein the first platform is coupled to the second platform.

In some embodiments, the techniques described herein relate to a microelectronic device, wherein the first plurality of conductive supports, the first plurality of compliant contacts, the second plurality of conductive supports, and the second plurality of compliant contacts are formed with a 3D lithographic process.

In some embodiments, the techniques described herein relate to a microelectronic device, further including a substrate including a plurality of contact pads, wherein the first plurality of conductive supports and the second plurality of conductive supports are electrically connected to the plurality of contact pads.

In some embodiments, the techniques described herein relate to a microelectronic device, wherein the first platform includes a plurality of TSVs extending through a thickness of the first platform. In some embodiments, the techniques described herein relate to a microelectronic device, wherein the plurality of TSVs electrically the first plurality of conductive supports with the first plurality of compliant contacts.

In some embodiments, the techniques described herein relate to a microelectronic device, wherein the first plurality of conductive supports and the first plurality of compliant contacts are compliant structures. In some embodiments, the techniques described herein relate to a microelectronic device, wherein the first plurality of conductive supports includes a first elastic modulus, wherein the first plurality of compliant contacts includes a second elastic modulus, and wherein the first elastic modulus is different than the second elastic modulus.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled,” as generally used herein, refers to two or more elements that may be either directly connected, or connected by way of one or more intermediate elements. Likewise, the word “connected,” as generally used herein, refers to two or more elements that may be either directly connected, or connected by way of one or more intermediate elements. Additionally, the words “herein,” “above,” “below,” and words of similar import, when used in this application, shall refer to this application as a whole and not to any particular portions of this application. Moreover, as used herein, when a first element is described as being “on” or “over” a second element, the first element may be directly on or over the second element, such that the first and second elements directly contact, or the first element may be indirectly on or over the second element such that one or more elements intervene between the first and second elements. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments.

While certain embodiments have been described, these embodiments have been presented by way of example only and are not intended to limit the scope of the disclosure. Indeed, the apparatus, methods, and systems described herein may be embodied in a variety of other forms; furthermore, various omissions, substitutions, and changes in the form of the methods and systems described herein may be made without departing from the spirit of the disclosure. Any suitable combination of the elements and acts of the various embodiments described above can be combined to provide further embodiments. The accompanying claims and their equivalents are intended to cover such forms or modifications as would fall within the scope and spirit of the disclosure.

1. A compliant contact comprising:
a body including and extending between a first end and a second end, wherein the second end is configured to couple to an electrically interfacing device; and
a conductive material, wherein the conductive material defines an outer surface of the body, wherein the body is formed with a 3D lithographic process and a metallization process.

2. The compliant contact of claim 1, wherein the conductive material comprises columnar grains that have an orientation that is about normal to an axis of elongation.

3. (canceled)

4. (canceled)

5. (canceled)

6. (canceled)

7. (canceled)

8. The compliant contact of claim 1, wherein the body comprises a core and a spring surrounding the core.

9. The compliant contact of claim 1, wherein the body comprises a compliant core.

10. The compliant contact of claim 1, wherein the body comprises a scaffold and the conductive material disposed over the scaffold, wherein the scaffold comprises a polymer.

11. (canceled)

12. (canceled)

13. (canceled)

14. The compliant contact of claim 1, wherein the body comprises a plurality of components including a first component and a second component, wherein the first component has a first elastic modulus, and wherein the second component has a second elastic modulus different than the first elastic modulus.

15. (canceled)

16. (canceled)

17. The compliant contact of claim 1, wherein the body comprises a plunger and a cavity.

18. (canceled)

19. (canceled)

20. The compliant contact of claim 1, wherein the body comprises a coil or a ribbon morphology, wherein the coil or the ribbon morphology extends from at least the first end of the compliant contact.

21. (canceled)

22. The compliant contact of claim 1, wherein the body comprises one or more compliant elements about a central axis and a tip along the central axis.

23. (canceled)

24. (canceled)

25. The compliant contact of claim 1, wherein the body comprises an external support structure surrounding a core, wherein the core is electrically conductive.

26. (canceled)

27. (canceled)

28. (canceled)

29. (canceled)

30. (canceled)

31. (canceled)

32. (canceled)

33. (canceled)

34. (canceled)

35. (canceled)

36. A method of forming a compliant contact, the method comprising:
forming a scaffold with a 3D lithographic process; and
forming a conductive layer over the scaffold, wherein the conductive layer defines an outer surface of the scaffold.

37. The method of claim 36, wherein the conductive layer comprises columnar grains that are normal to a surface of the scaffold on which it is formed.

38. The method of claim 36, wherein the scaffold comprises a polymer.

39. The method of claim 36, further comprising forming a tip, wherein the tip comprises a shape, wherein the shape comprises a sphere, a hyperboloid, a pyramid, a wedge, a crown, a multi-wedge, a screw tip, or multiple contact protrusions.

40. (canceled)

41. The method of claim 36, further comprising forming one or more voids and removing the scaffold through the one or more voids.

42. (canceled)

43. (canceled)

44. The method of claim 36, wherein the scaffold comprises a plurality of template elements.

45. The method of claim 36, wherein the scaffold comprises a first portion for forming a core, wherein the scaffold comprises a second portion for forming one or more beams or coils to surround the core.

46. (canceled)

47. (canceled)

48. A microelectronic device comprising:
a substrate comprising a plurality of contact pads; and
a plurality of compliant contacts disposed over and electrically connected to the plurality of contact pads, wherein the plurality of compliant contacts comprises a first compliant contact formed with a 3D lithographic process and a metallization process.

49. (canceled)

50. (canceled)

51. (canceled)

52. (canceled)

53. (canceled)

54. The microelectronic device of claim 48, wherein the first compliant contact comprises a scaffold and a conductive material disposed over the scaffold.

55. (canceled)

56. (canceled)

57. (canceled)

58. The microelectronic device of claim 48, wherein the plurality of compliant contacts comprises nested compliant contacts.

59. (canceled)

60. (canceled)

61. (canceled)

62. (canceled)

63. (canceled)

64. The microelectronic device of claim 48, further comprising a porous material, wherein the first compliant contact comprises a coil and a tip, wherein the coil extends from a first contact pad of the plurality of contact pads, wherein the coil is embedded in the porous material and the tip is above the porous material.

65. (canceled)

66. (canceled)

67. (canceled)

68. (canceled)

69. (canceled)

70. (canceled)

71. (canceled)

72. (canceled)

73. (canceled)

74. (canceled)

75. The microelectronic device of claim 48, further comprising a plurality of sub-arrays of compliant contacts, including a first sub-array of compliant contacts and a second sub-array of compliant contacts, wherein the first sub-array of compliant contacts comprises the plurality of compliant contacts, wherein the second sub-array of compliant contacts comprises a second plurality of compliant contacts, and wherein an individual sub-array of compliant contacts of the plurality of sub-arrays of compliant contacts is removable.

76. (canceled)

77. The microelectronic device of claim 48, further comprising a multi-level hierarchical configuration, wherein the multi-level hierarchical configuration comprises a first layer of conductive supports, a second layer of platforms, and a third layer of compliant contacts, wherein the first layer of conductive supports are electrically connected to the plurality of contact pads, wherein the conductive supports are disposed below the second layer of platforms, wherein the third layer of compliant contacts are disposed above the second layer of platforms, and wherein the third layer of compliant contacts comprises the plurality of compliant contacts.

78. (canceled)

79. The microelectronic device of claim 48, wherein the first compliant contact comprises a spring surrounding a core, wherein the core comprises a male portion and a female portion, wherein the male portion is configured to couple with the female portion.

80. (canceled)

81. (canceled)

82. (canceled)

83. (canceled)

84. The microelectronic device of claim 48, wherein the first compliant contact comprises a coil structure to reduce a compressive force to establish electrical contact between the first compliant contact and a device under test.

85. (canceled)

86. (canceled)

87. (canceled)

88. (canceled)

89. (canceled)

90. (canceled)

91. (canceled)

92. (canceled)

93. (canceled)

94. (canceled)

95. (canceled)

96. (canceled)

97. (canceled)

98. (canceled)

99. (canceled)

100. (canceled)

101. (canceled)

102. (canceled)

103. (canceled)

104. (canceled)

105. (canceled)

106. (canceled)

107. (canceled)

108. (canceled)

109. (canceled)

110. (canceled)

111. (canceled)

112. (canceled)

113. (canceled)

114. (canceled)

115. (canceled)

116. (canceled)

117. (canceled)

118. (canceled)

119. (canceled)

120. (canceled)

121. (canceled)
